(19) United States
(12) Patent Application Publication
(10) Pub. No.: US 2026/0136591 A1
(43) Pub. Date: May 14, 2026

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/443,024

(22) Filed: Jan. 8, 2026

Related U.S. Application Data
(63) Continuation of application No. PCT/JP2024/021289, filed on Jun. 12, 2024.

(30) Foreign Application Priority Data
Jul. 20, 2023 (JP) 2023-118662

(51) Int. Cl. H10D 30/66; H10D 12/00; H10D 12/01; H10D 30/01; H10D 62/10; H10D 62/832

(52) U.S. Cl. CPC H10D 30/665; H10D 12/415; H10D 12/481; H10D 30/668; H10D 62/102; H10D 62/8325; H10D 12/038; H10D 30/0297

(57) ABSTRACT

A semiconductor device includes first, second, and third impurity regions of alternating conductivity types formed in surface layer portions of a chip. A trench extends from a first principal surface to the first impurity region, and an electric field relaxation structure of the second conductivity type is formed at a bottom of the trench. First and second contact regions are formed along opposite side surfaces of the trench from the first principal surface toward a second principal surface. The first and second contact regions are electrically connected to the second impurity region and the electric field relaxation structure. A plurality of the first contact regions and a plurality of the second contact regions are arranged along a length direction of the trench.

### CROSS-REFERENCE TO RELATED APPLICATIONS

The present application is a bypass continuation application of International Patent Application No. PCT/JP 2024/021289, filed on Jun. 12, 2024, which corresponds to Japanese Patent Application No. 2023-118662, filed on Jul. 20, 2023 with the Japan Patent Office, and the entire disclosure of these applications are incorporated herein by reference.

### TECHNICAL FIELD

The present disclosure relates to a semiconductor device.

### Background Art

Patent Literature 1 (US 2015/0028351 A1 Specification) discloses an electronic device having an impurity region introduced into a silicon carbide layer by a channeling implantation method.

### BRIEF DESCRIPTION OF DRAWINGS

FIG. 1 is a plan view showing a semiconductor device according to a preferred embodiment of the present disclosure.

FIG. 2 is a sectional view taken along line II-II shown in FIG. 1.

FIG. 3 is a plan view showing a layout example of a chip.

FIG. 4 is a perspective view showing the layout example of the chip.

FIG. 5 is a plan view showing an active region and a trench structure.

FIG. 6 is a sectional view taken along line VI-VI shown in FIG. 5.

FIG. 7 is a sectional perspective view corresponding to FIG. 6.

FIG. 8 is a sectional view taken along line VIII-VIII shown in FIG. 5.

FIG. 9 is a sectional perspective view corresponding to FIG. 8.

FIG. 10 is a sectional view taken along line X-X shown in FIG. 5.

FIG. 11 is a perspective view showing an arrangement of an outer peripheral region.

FIG. 12 is a sectional view showing a principal portion of the outer peripheral region.

FIG. 13 is a schematic view showing a wafer used in manufacture of the semiconductor device.

FIG. 14 is a flowchart showing a manufacturing method example of the semiconductor device.

FIG. 15A to FIG. 15G are views showing the manufacturing method example of the semiconductor device.

FIG. 16 is a view showing a first modification example of the semiconductor device.

FIG. 17 is a view showing a second modification example of the semiconductor device.

FIG. 18 is a sectional view taken along line XVIII-XVIII shown in FIG. 17.

FIG. 19 is a view showing a third modification example of the semiconductor device.

FIG. 20 is a view showing a fourth modification example of the semiconductor device.

FIG. 21 is a view showing a fifth modification example of the semiconductor device.

FIG. 22 is a view showing a sixth modification example of the semiconductor device.

### DESCRIPTION OF EMBODIMENTS

Next, a preferred embodiment of the present disclosure shall be described in detail with reference to the attached drawings.

The attached drawings are all schematic views and are not strictly illustrated, and scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type,” the “p-type” may be referred to as a “first conductivity type,” and the “n-type” may be referred to as a “second conductivity type.” As a matter of course, the “n-type” may be referred to as the “first conductivity type,” and the “p-type” may be referred to as the “second conductivity type” instead. The “p-type” is a conductivity type due to a trivalent element and the “n-type” is a conductivity type due to a pentavalent element. Unless noted in particular otherwise, the trivalent element is at least one type among boron, aluminum, gallium, and indium. Unless noted in particular otherwise, the pentavalent element is at least one type among nitrogen, phosphorus, arsenic, antimony, and bismuth.

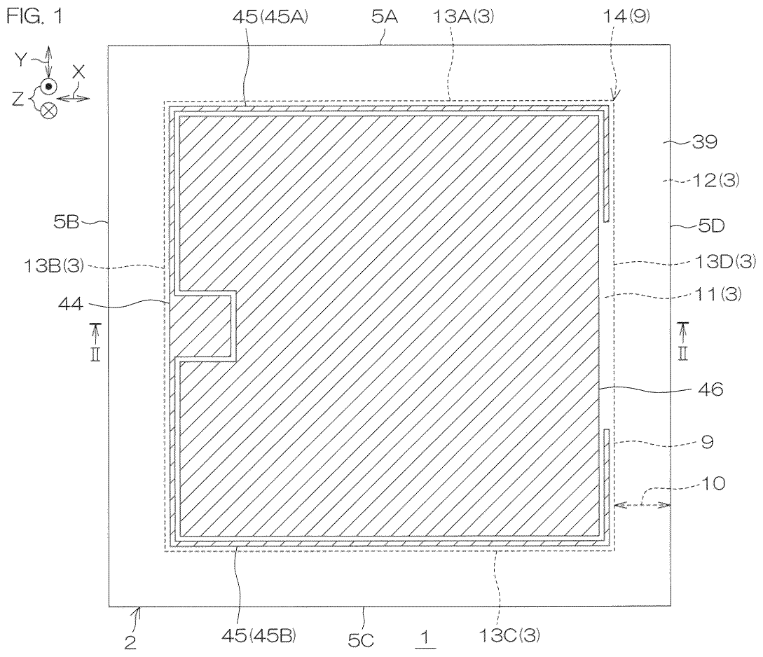

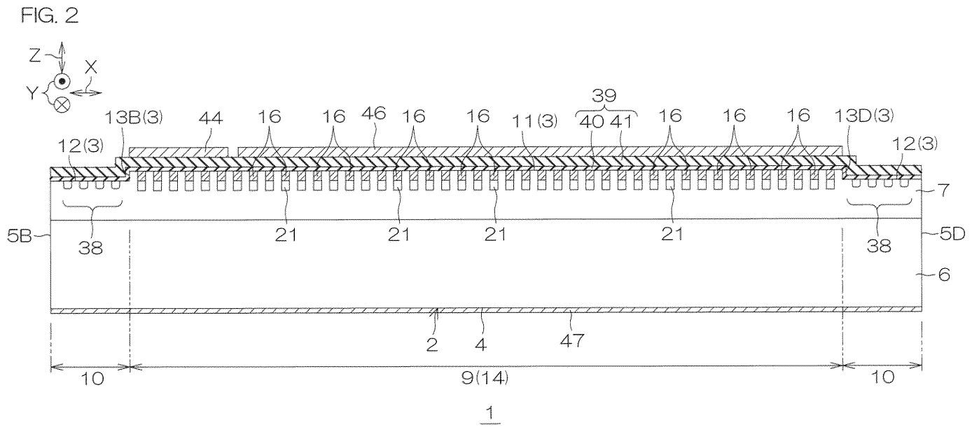

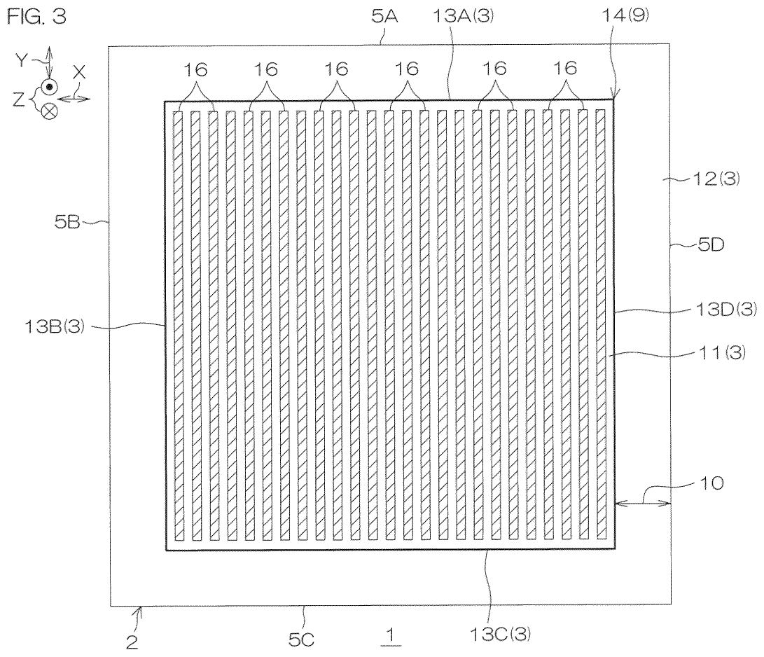

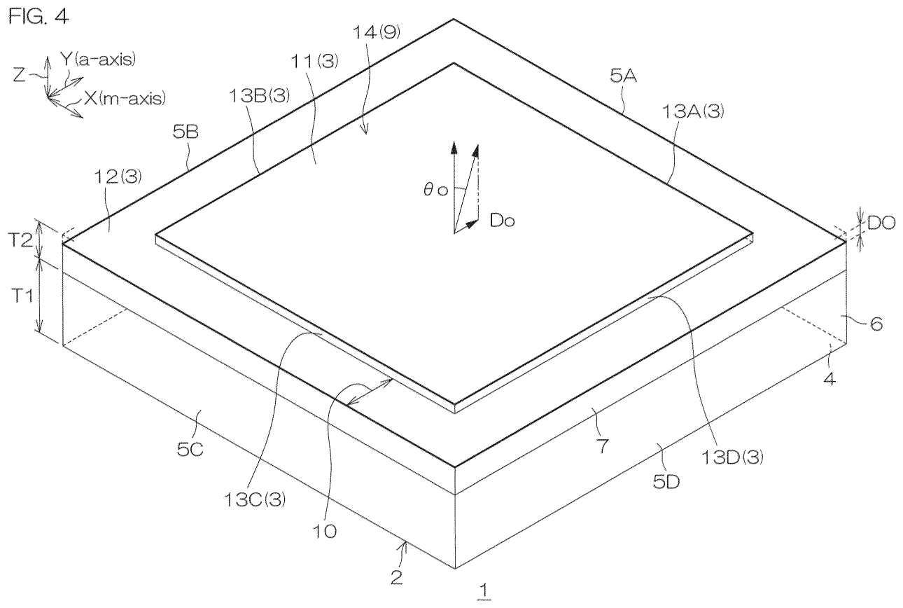

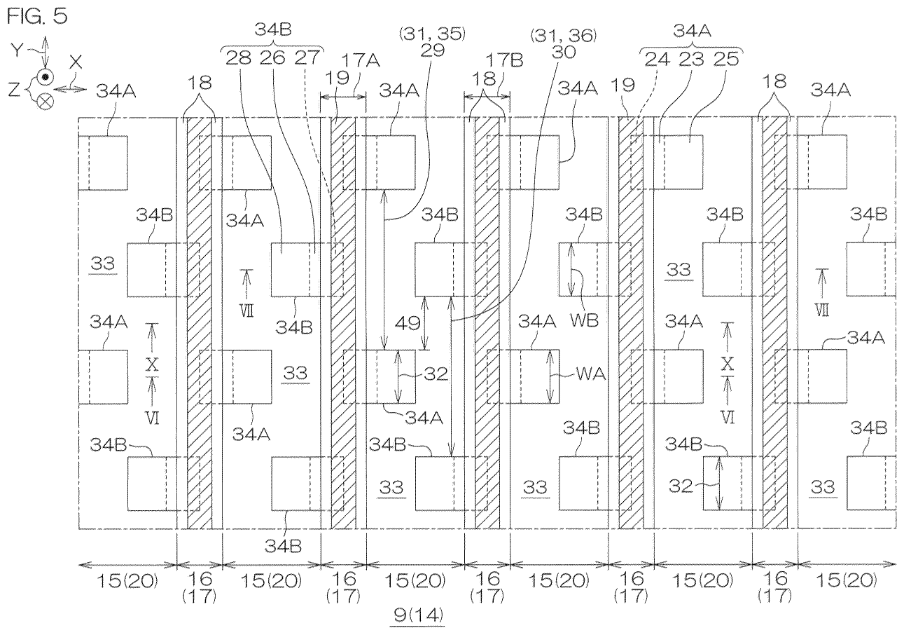

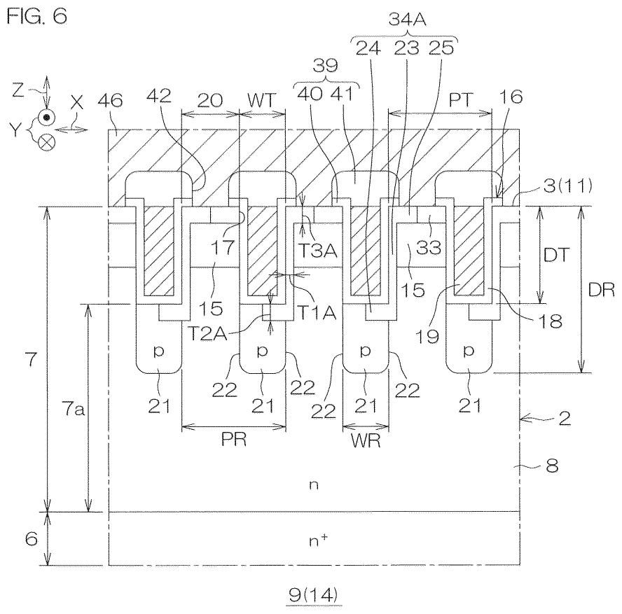

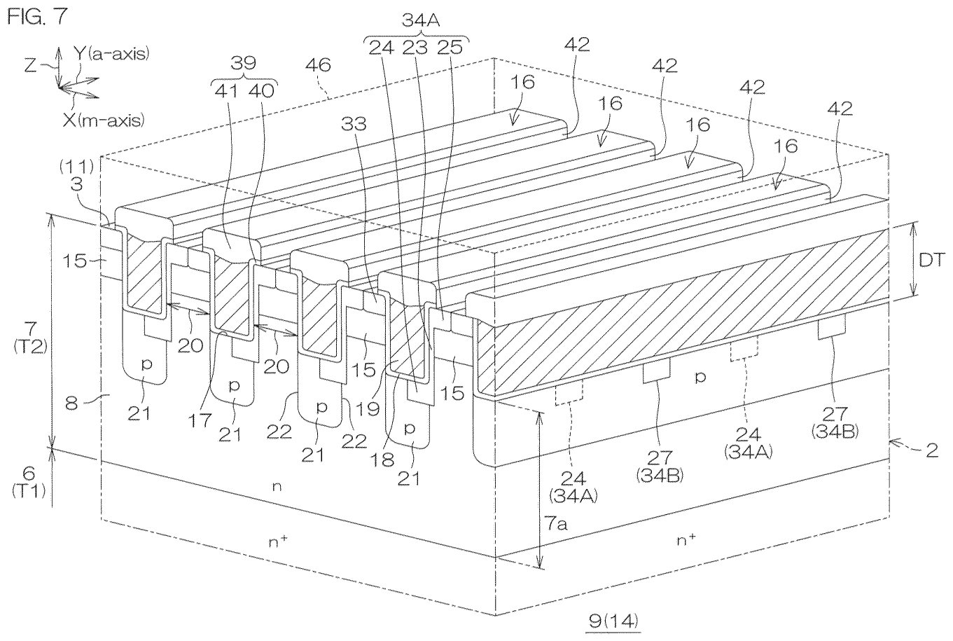

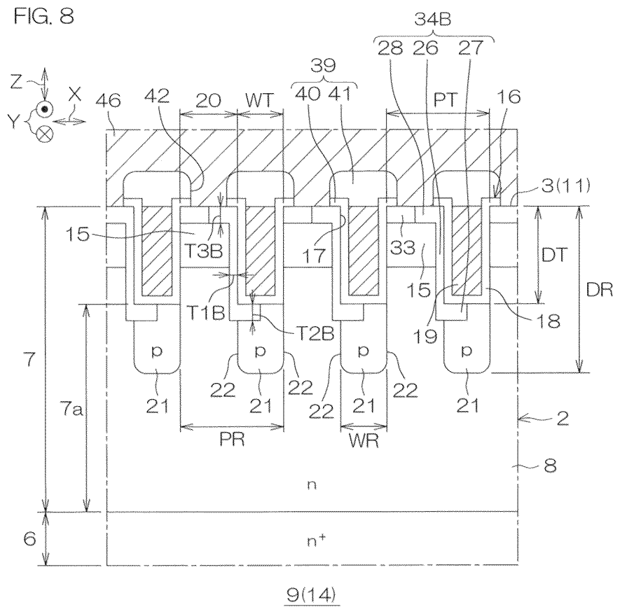

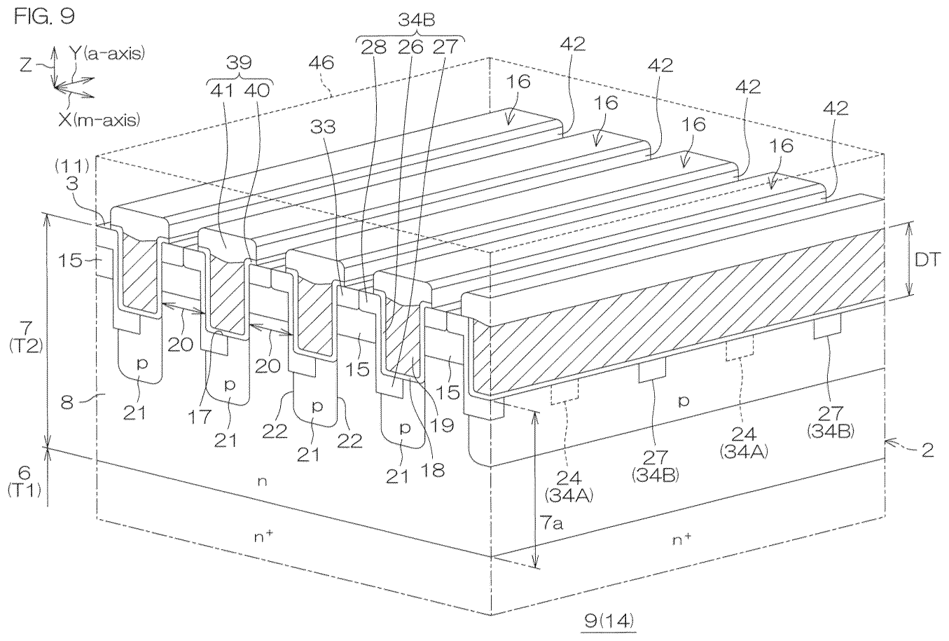

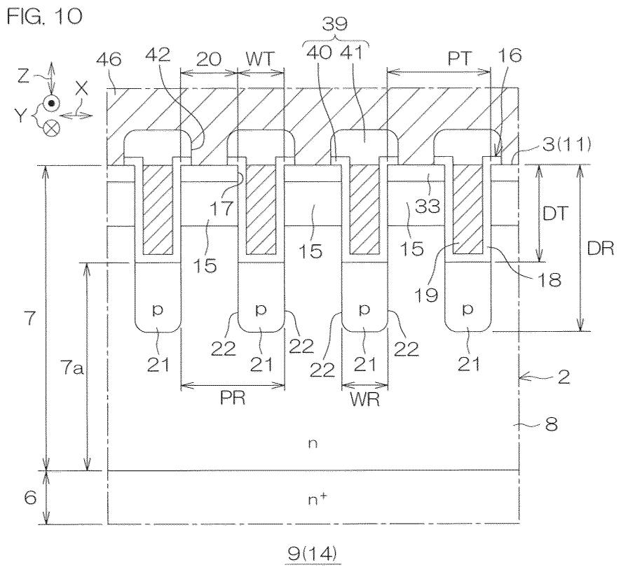

FIG. 1 is a plan view showing a semiconductor device 1 according to the preferred embodiment. FIG. 2 is a sectional view taken along line II-II shown in FIG. 1. FIG. 3 is a plan view showing a layout example of a chip 2. FIG. 4 is a perspective view showing the layout example of the chip 2. FIG. 5 is a plan view showing trench structures 16 together with an active region 9. FIG. 6 is a sectional view taken along line VI-VI shown in FIG. 5. FIG. 7 is a sectional perspective view corresponding to FIG. 6. FIG. 8 is a sectional view taken along line VIII-VIII shown in FIG. 5. FIG. 9 is a sectional perspective view corresponding to FIG. 8. FIG. 10 is a sectional view taken along line X-X shown in FIG. 5.

With reference to FIG. 1 to FIG. 10, the semiconductor device 1 includes the chip 2 that includes an SiC monocrystal. The chip 2 may be referred to as an “SiC chip” or a “semiconductor chip.” In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H—SiC monocrystal, etc. In this embodiment, an example in which the chip 2 is constituted of the 4H—SiC monocrystal is to be given, but the chip 2 may be constituted of another polytype instead.

The chip 2 has a first principal surface 3 on one side, a second principal surface 4 on the other side, and first to fourth side surfaces 5A to 5D connecting the first principal surface 3 and the second principal surface 4. In a plan view as viewed from a vertical direction Z (hereinafter referred to simply as “plan view”), the first principal surface 3 and the second principal surface 4 are formed in quadrilateral shapes. The vertical direction Z is also a thickness direction of the chip 2 and a normal direction to the first principal surface 3 (the second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane (a (0001) plane) of the SiC monocrystal and the second principal surface 4 is formed by a carbon plane (a (000-1) plane) of the SiC monocrystal.

In regard to a circumferential direction of the chip 2 with the first side surface 5A as a starting point (counterclockwise in FIG. 1), the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X oriented along the first principal surface 3 and are opposed in a second direction Y intersecting (specifically, orthogonal to) the first direction X. The second side surface 5B and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. As a matter of course, the first direction X may instead be the a-axis direction of the SiC monocrystal and the second direction Y may instead be the m-axis direction of the SiC monocrystal.

An XY plane that includes the first direction X and the second direction Y forms a horizontal plane that is orthogonal to the vertical direction Z. In the following, an axis extending along the vertical direction Z is expressed at times as a “vertical axis.” Also, in the following, the first direction X and the second direction Y is expressed at times as “horizontal directions.” Horizontal directions are also directions that extend along the first principal surface 3.

With reference to FIG. 4, the chip 2 (the first principal surface 3 and the second principal surface 4) has an off angle θo inclined at a predetermined angle in a predetermined off direction Do with respect to the c-plane of the SiC monocrystal. That is, a c-axis (a (0001) axis) of the SiC monocrystal is inclined by just the off angle θo toward the off direction Do from the vertical axis. Also, the c-plane of the SiC monocrystal is inclined by just the off angle θo with respect to the horizontal plane.

The off direction Do is preferably the a-axis direction (that is, the second direction Y) of the SiC monocrystal. The off angle θo may exceed 0° and be not more than 10°. The off angle θo may have a value belonging to any one range among exceeding 0° and not more than 1°, not less than 1° and not more than 2.5°, not less than 2.5° and not more than 5°, not less than 5° and not more than 7.5°, and not less than 7.5° and not more than 10°.

The off angle θo is preferably not more than 5°. The off angle θo is particularly preferably not less than 2° and not more than 4.5°. The off angle θo is typically set in a range of 4°±0.1°. As a matter of course, this Description does not exclude an embodiment in which the off angle θo is 0° (that is, an embodiment in which the first principal surface 3 is a just surface with respect to the c-plane).

The chip 2 includes a base layer 6 of an n-type that is constituted of an SiC monocrystal. The base layer 6 may be referred to as a “drain region,” a “base SiC layer,” a “base region,” etc. The base layer 6 extends in a layered shape in the horizontal directions and forms the second principal surface 4 and portions of the first to fourth side surfaces 5A to 5D. In this embodiment, the base layer 6 is constituted of a substrate made of the SiC monocrystal (in other words, an SiC substrate). The base layer 6 has the off direction Do and the off angle θo described above.

The base layer 6 may have an n-type impurity concentration of not less than 1×10¹⁸ cm⁻³ and not more than 1×10²¹ cm⁻³ as a peak value. The base layer 6 preferably has an n-type impurity concentration that is substantially fixed in a thickness direction. The n-type impurity concentration of the base layer 6 is preferably adjusted by a single type of pentavalent element. The n-type impurity concentration of the base layer 6 is particularly preferably adjusted by a pentavalent element other than phosphorus. In this embodiment, the n-type impurity concentration of the base layer 6 is adjusted by nitrogen.

The base layer 6 has a first thickness T1. The first thickness T1 may be not less than 5 μm and not more than 300 μm. The first thickness T1 may have a value belonging to any one range among not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, and not less than 250 μm and not more than 300 μm. The first thickness T1 is preferably not less than 50 μm and not more than 250 μm.

The chip 2 includes a semiconductor layer 7 made of the SiC monocrystal that is laminated on the base layer 6. The semiconductor layer 7 as an example of a first impurity region may be referred to as a “drift region,” an “SiC layer,” a “semiconductor region,” etc. The semiconductor layer 7 extends in a layered shape in the horizontal directions and forms the first principal surface 3 and portions of the first to fourth side surfaces 5A to 5D. The semiconductor layer 7 is constituted of an epitaxial layer (that is, an SiC epitaxial layer) formed by crystal growth with the base layer 6 as a starting point.

The semiconductor layer 7 has a lower end and an upper end. The lower end of the semiconductor layer 7 is a crystal growth starting point and the upper end of the semiconductor layer 7 is a crystal growth end point. The lower end of the semiconductor layer 7 is also a bottom portion of the semiconductor layer 7. The semiconductor layer 7 is formed by continuous crystal growth from the base layer 6 and therefore, the lower end of the semiconductor layer 7 coincides with an upper end of the base layer 6.

The semiconductor layer 7 includes a drift region 8 of the n-type. In this embodiment, the drift region 8 is formed by a portion of the semiconductor layer 7 (a portion of the n-type). In more detail, the drift region 8 is formed by the portion of the semiconductor layer 7 on the second principal surface 4 side with respect to a body region 15 (to be described below) and an electric field relaxation structure 21 (to be described below) in the vertical direction Z.

A boundary portion between the base layer 6 and the semiconductor layer 7 is not necessarily visually recognizable and can be evaluated and/or determined indirectly from other arrangements and elements. The semiconductor layer 7 has an off direction Do and the off angle θo that substantially coincide with the off direction Do and the off angle θo of the base layer 6.

An n-type impurity concentration of the semiconductor layer 7 (the drift region 8) is preferably less than the n-type impurity concentration of the base layer 6. The semiconductor layer 7 may have an n-type impurity concentration of not less than 1×10¹⁵ cm⁻³ and not more than 1×10¹⁸ cm⁻³ as a peak value. The n-type impurity concentration of the semiconductor layer 7 may be substantially fixed in a thickness direction. As a matter of course, the n-type impurity concentration of the semiconductor layer 7 may have a concentration gradient that increases gradually and/or decreases gradually in a lamination direction (a crystal growth direction).

In this embodiment, the n-type impurity concentration of the semiconductor layer 7 is adjusted by nitrogen. The semiconductor layer 7 may have an n-type impurity concentration that is adjusted by at least one type of pentavalent element. For example, the n-type impurity concentration of the semiconductor layer 7 may be adjusted by at least one type among nitrogen, phosphorus, arsenic, antimony, and bismuth. The semiconductor layer 7 preferably contains a pentavalent element other than phosphorus.

The semiconductor layer 7 has a second thickness T2 less than the first thickness T1. The second thickness T2 may be not less than 1 μm and not more than 10 μm. The second thickness T2 may have a value belonging to any one range among not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The second thickness T2 is preferably not less than 2 μm and not more than 8 μm.

The semiconductor device 1 includes the active region 9 set in the chip 2. The active region 9 is set in an inner portion of the chip 2 at intervals from peripheral edges (the first to fourth side surfaces 5A to 5D) of the chip 2 in plan view. The active region 9 is set in a polygonal shape (in this embodiment, a quadrilateral shape) having four sides parallel to the peripheral edges of the chip 2 in plan view. A planar area of the active region 9 is preferably not less than 50% and not more than 90% of a planar area of the first principal surface 3.

The semiconductor device 1 includes an outer peripheral region 10 that, in the chip 2, is set outside the active region 9. The outer peripheral region 10 is provided in a region between the peripheral edges of the chip 2 and the active region 9 in plan view. The outer peripheral region 10 extends in a band shape along the active region 9 and is set to a polygonal annular shape (in this embodiment, a quadrilateral annular shape) that surrounds the active region 9 in plan view.

The semiconductor device 1 includes an active surface 11, an outer surface 12, and first to fourth connecting surfaces 13A to 13D that are formed in the first principal surface 3. The active surface 11, the outer surface 12, and the first to fourth connecting surfaces 13A to 13D demarcate an active mesa 14 in the first principal surface 3.

The active surface 11 may be referred to as a “first surface portion,” the outer surface 12 may be referred to as a “second surface portion,” the first to fourth connecting surfaces 13A to 13D may be referred to as “connecting surface portions,” and the active mesa 14 may be referred to as an “active mesa portion.” The active surface 11, the outer surface 12, and the first to fourth connecting surfaces 13A to 13D (that is, the active mesa 14) may be considered as components of the chip 2 (the first principal surface 3).

The active surface 11 is formed in the active region 9. That is, the active surface 11 is formed at intervals inward from the peripheral edges of the first principal surface 3 (from the first to fourth side surfaces 5A to 5D). The active surface 11 has a flat surface extending in the first direction X and the second direction Y. In this embodiment, the active surface 11 is formed by the c-plane (an Si plane). In this embodiment, the active surface 11 is formed in a quadrilateral shape having four sides parallel to the first to fourth side surfaces 5A to 5D in plan view.

The outer surface 12 is formed in the outer peripheral region 10. That is, the outer surface 12 is formed outside the active surface 11. The outer surface 12 is recessed in the thickness direction of the chip 2 (toward the second principal surface 4 side) with respect to the active surface 11. Specifically, in this embodiment, the outer surface 12 is recessed to a depth less than the thickness of the semiconductor layer 7 such as to expose the semiconductor layer 7. That is, the outer surface 12 faces the base layer 6 with a portion of the semiconductor layer 7 interposed therebetween and exposes the semiconductor layer 7.

The outer surface 12 extends in a band shape along the active surface 11 in plan view and is formed in an annular shape (specifically, a quadrilateral annular shape) surrounding the active surface 11. The outer surface 12 has a flat surface extending in the first direction X and the second direction Y and is formed substantially parallel to the active surface 11. In this embodiment, the outer surface 12 is formed by the c-plane (the Si plane). The outer surface 12 is continuous to the first to fourth side surfaces 5A to 5D.

The outer surface 12 has an outer peripheral depth DO. The outer peripheral depth DO may be not less than 0.1 μm and not more than 2 μm. The outer peripheral depth DO may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, and not less than 1.5 μm and not more than 2 μm. The outer peripheral depth DO is preferably not less than 0.1 μm and not more than 1.5 μm.

The first to fourth connecting surfaces 13A to 13D extend in the vertical direction Z and connect the active surface 11 and the outer surface 12. The first connecting surface 13A is positioned at the first side surface 5A side, the second connecting surface 13B is positioned at the second side surface 5B side, the third connecting surface 13C is positioned at the third side surface 5C side, and the fourth connecting surface 13D is positioned at the fourth side surface 5D side. The first connecting surface 13A and the third connecting surface 13C extend in the first direction X and are opposed in the second direction Y. The second connecting surface 13B and the fourth connecting surface 13D extend in the second direction Y and are opposed in the first direction X.

The first to fourth connecting surfaces 13A to 13D may extend substantially vertically between the active surface 11 and the outer surface 12 such as to demarcate the active mesa 14 of a quadrilateral columnar shape. The first to fourth connecting surfaces 13A to 13D may be inclined obliquely downward from the active surface 11 toward the outer surface 12 such as to demarcate the active mesa 14 of a quadrilateral pyramid shape instead. The active mesa 14 is thus demarcated in a projecting shape on the semiconductor layer 7 in the first principal surface 3. The active mesa 14 is formed just on the semiconductor layer 7 and is not formed on the base layer 6.

With reference to FIG. 5 to FIG. 10, the semiconductor device 1 includes the body region 15 of the p-type formed in a surface layer portion of the first principal surface 3 (the active surface 11). In this embodiment, the body region 15 as an example of a second impurity region is formed in a layered shape extending along the active surface 11. The body region 15 may be formed in an entirety of the active surface 11 and may be exposed from the first to fourth connecting surfaces 13A to 13D. The body region 15 is formed at an interval to the active surface 11 side from the lower end of the semiconductor layer 7. The body region 15 is preferably formed at an interval to the active surface 11 side from a depth position of the outer surface 12 and is exposed from the active surface 11.

The body region 15 may have a p-type impurity concentration of not less than 1×10¹⁵ cm⁻³ and not more than 1×10¹⁸ cm⁻³ as a peak value. The p-type impurity concentration of the body region 15 is preferably adjusted by at least one type of trivalent element. The trivalent element of the body region 15 may be at least one type among boron, aluminum, gallium, and indium.

The semiconductor device 1 includes the plurality of trench structures 16 of a trench electrode type that are formed in the first principal surface 3 (the active surface 11) in the active region 9. The trench structures 16 may be referred to as “gate structures,” “trench gate structures,” etc. A gate potential is applied as a control potential to the plurality of trench structures 16. The plurality of trench structures 16 control inversion and non-inversion of channels (current paths) inside the body region 15 in response to the gate potential.

The plurality of trench structures 16 are arranged at intervals inward from peripheral edges of the active surface 11 (from the first to fourth connecting surfaces 13A to 13D) in the active region 9. In this embodiment, the plurality of trench structures 16 are arranged at intervals in the first direction X and are each formed in a band shape extending in the second direction Y.

That is, the plurality of trench structures 16 are arranged at intervals in the m-axis direction and each extend in the a-axis direction. Also, in this embodiment, the plurality of trench structures 16 are arranged as stripes extending in the a-axis direction (the second direction Y). An extension direction of the plurality of trench structures 16 coincides with the off direction Do of the semiconductor layer 7.

The plurality of trench structures 16 are formed at intervals to the first principal surface 3 (the active surface 11) side from the lower end of the semiconductor layer 7 (from the base layer 6) and faces the base layer 6 with a portion of the semiconductor layer 7 interposed therebetween. The plurality of trench structures 16 demarcate a lower region 7a in a region between bottom walls of the plurality of trench structures 16 and the lower end of the semiconductor layer 7 (the base layer 6).

Each trench structure 16 has a trench width WT in an arrangement direction and has a trench depth DT in the vertical direction Z. The trench width WT is preferably less than the second thickness T2 of the semiconductor layer 7. The trench width WT may be not less than 0.1 μm and not more than 5μm.

The trench width WT may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The trench depth DT is preferably less than the second thickness T2 of the semiconductor layer 7. The trench depth DT is particularly preferably substantially equal to the outer peripheral depth DO described above. As a matter of course, the trench depth DT may be not less than the outer peripheral depth DO or may be less than the outer peripheral depth DO.

The trench depth DT is preferably greater than the trench width WT. That is, the plurality of trench structures 16 each preferably have an aspect ratio DT/WT of extending in a vertically long columnar shape. The aspect ratio DT/WT is a ratio of the trench width WT with respect to the trench depth DT. The aspect ratio DT/WT may be, for example, not less than 1 and not more than 5, and preferably not less than 1 and not more than 3.

The trench depth DT may be not less than 0.1 μm and not more than 5 μm. The trench depth DT may have a value belonging to any one range among not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The trench depth DT is preferably not less than 0.1 μm and not more than 1.5 μm, and more preferably not less than 0.5 μm and not more than 1.5 μm.

The plurality of trench structures 16 are arranged at intervals, each of a trench pitch PT, in the first direction X. The trench pitch PT is preferably less than the second thickness T2 of the semiconductor layer 7. The trench pitch PT is preferably less than the trench depth DT. The trench pitch PT may be not less than 0.1 μm and not more than 5 μm.

The trench pitch PT may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The trench pitch PT is preferably not less than 0.5 μm and not more than 3 μm, and more preferably not less than 0.5 μm and not more than 1.5 μm.

Each trench structure 16 includes a trench 17, an insulating film 18, and an embedded electrode 19. The trench 17 is formed in the active surface 11 and demarcates wall surfaces (side walls and a bottom wall) of the trench structure 16. A bottom wall of the trench 17 preferably has a portion that extends flatly. A mesa portion 20 formed by a portion of the semiconductor layer 7 is formed between the trenches 17 that are mutually adjacent. The mesa portion 20 may be referred to as an “element mesa portion.” In this embodiment, a plurality of the trenches 17 and a plurality of the mesa portions 20 are each formed in a band shape extending along the second direction Y and are alternately arranged in the first direction X. The plurality of trenches 17 and the plurality of mesa portions 20 are arranged as stripes as a whole.

A flat portion of the bottom wall of the trench 17 particularly preferably extends substantially parallel to the first principal surface 3. That is, the bottom wall of the trench 17 preferably has the off angle θo inclined at a predetermined angle in a predetermined off direction Do with respect to the c-plane. That is, the bottom wall of the trench 17 preferably has a flat portion that extends in the off direction Do. As a matter of course, the bottom wall of the trench 17 may instead be curved in an arcuate shape toward the lower end side of the semiconductor layer 7.

The insulating film 18 covers wall surfaces of the trench 17. The insulating film 18 may include at least one among a silicon oxide film, a silicon nitride film, and a silicon oxynitride film. In this embodiment, the insulating film 18 has a single layer structure constituted of the silicon oxide film. The insulating film 18 particularly preferably includes the silicon oxide film constituted of an oxide of the chip 2.

The embedded electrode 19 is embedded in the trench 17 and faces the channel with the insulating film 18 interposed therebetween. In this embodiment, the embedded electrode 19 faces the body region 15 with the insulating film 18 interposed therebetween. The embedded electrode 19 may contain a conductive polysilicon of the p-type or the n-type.

The semiconductor device 1 includes a plurality of the electric field relaxation structures 21 of the p-type formed at intervals in the horizontal direction inside the semiconductor layer 7. Specifically, the plurality of electric field relaxation structures 21 are formed in the lower region 7a inside the semiconductor layer 7. The plurality of electric field relaxation structures 21 are formed in a thickness range between the lower end of the semiconductor layer 7 and the bottom walls of the plurality of trench structures 16.

Inside the lower region 7a, the plurality of electric field relaxation structures 21 are arranged at intervals in the first direction X and are each formed in a band shape extending in the second direction Y. That is, the plurality of electric field relaxation structures 21 are arranged at intervals in the m-axis direction and extend in the a-axis direction of the SiC monocrystal. The plurality of electric field relaxation structures 21 are formed as stripes extending in the a-axis direction (the second direction Y) and an extension direction of the plurality of electric field relaxation structures 21 coincides with the off direction Do of the semiconductor layer 7.

The plurality of electric field relaxation structures 21 overlap the plurality of trench structures 16 in the lamination direction. Specifically, the plurality of electric field relaxation structures 21 overlap the plurality of trench structures 16 in the lamination direction in a one-to-one correspondence relationship. The plurality of electric field relaxation structures 21 are formed at intervals inward from the peripheral edges of the active surface 11 (from the first to fourth connecting surfaces 13A to 13D) in the active region 9.

In this embodiment, the plurality of electric field relaxation structures 21 are connected to bottom walls of the corresponding trench structures 16, respectively. An upper end portion of the electric field relaxation structure 21 is thereby exposed to the bottom wall of the trench structure 16 (the trench 17). Specifically, each electric field relaxation structure 21 has side surfaces 22 which are continuously flush with both side surfaces of each trench 17 in a depth direction of the trench structure 16. The side surface 22 of the electric field relaxation structure 21 extends in the depth direction of the trench structures 16 and forms a boundary surface with the semiconductor layer 7 (the lower region 7a). Therefore, the electric field relaxation structure 21 is physically separated from the body region 15 in the depth direction of the trench structure 16 and forms the entire bottom wall of the trench structure 16.

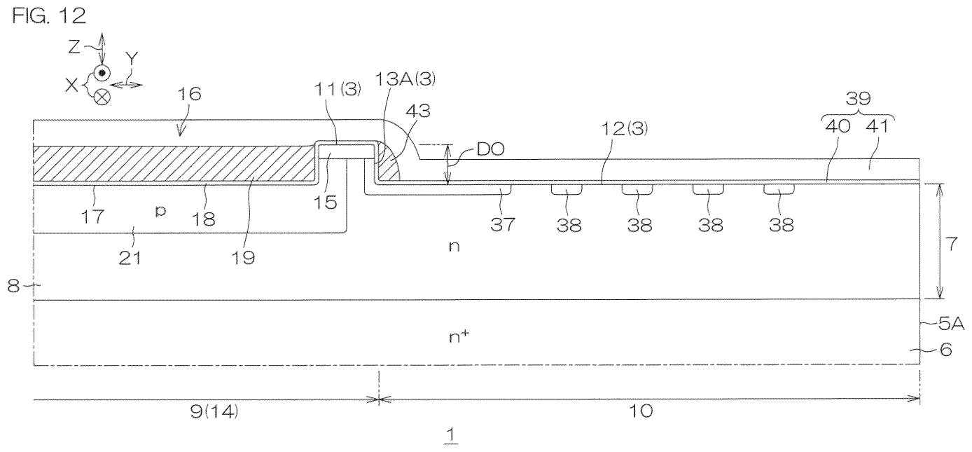

In the second direction Y, both end portions of the plurality of electric field relaxation structures 21 may be positioned on peripheral edge sides of the active region 9 with respect to both end portions of the plurality of trench structures 16 as shown in FIG. 12. The both end portions of the plurality of electric field relaxation structures 21 may instead be positioned on inner sides of the active region 9 with respect to the both end portions of the plurality of trench structures 16.

With reference to FIG. 6 and FIG. 8, the plurality of electric field relaxation structures 21 are arranged at intervals, each of a relaxation pitch PR, in the first direction X. The relaxation pitch PR may be equal to the trench pitch PT. The relaxation pitch PR may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The relaxation pitch PR is preferably not less than 0.5 μm and not more than 3.0 μm.

A p-type impurity concentration of the electric field relaxation structure 21 is preferably higher than the p-type impurity concentration of the body region 15. The electric field relaxation structure 21 may have a p-type impurity concentration of not less than 1×10¹⁶ cm⁻³ and not more than 1×10¹⁹ cm⁻³ as a peak value. The p-type impurity concentration of the electric field relaxation structure 21 may be substantially fixed in a thickness direction. As a matter of course, the p-type impurity concentration of the electric field relaxation structure 21 may have a concentration gradient that increases gradually and/or decreases gradually in the lamination direction (crystal growth direction).

The electric field relaxation structure 21 has a relaxation depth DR greater than the depth of the trench 17 in the vertical direction Z. More preferably, the relaxation depth DR of the electric field relaxation structure 21 is not less than twice the trench depth DT. As a matter of course, the relaxation depth DR may be less than twice the trench depth DT.

The relaxation depth DR may have a value belonging to any one range among exceeding 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The relaxation depth DR is preferably not less than 2 μm and not more than 3 μm, and in this case, the trench depth DT is preferably not less than 0.5 μm and not more than 1.5 μm.

The plurality of electric field relaxation structures 21 each have a relaxation width WR in the arrangement direction. The relaxation width WR may be not less than 0.25 μm and not more than 5 μm. The relaxation width WR may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor device 1 includes a plurality of contact regions 34A and 34B that are formed in regions between the plurality of trench structures 16 in the surface layer portion of the first principal surface 3 (the active surface 11). The plurality of contact regions 34A and 34B are both formed in the surface layer portion of the body region 15 and are physically separated from each other.

The plurality of contact regions 34A and 34B have a p-type impurity concentration (a peak value) higher than the p-type impurity concentration (the peak value) of the body region 15. The p-type impurity concentration (the peak value) of the plurality of contact regions 34 is higher than the p-type impurity concentration (the peak value) of the plurality of electric field relaxation structures 21. The plurality of contact regions 34A and 34B may have a p-type impurity concentration of not less than 1×10¹⁸ cm⁻³ and not more than 1×10²¹ cm⁻³ as a peak value. In this embodiment, the plurality of contact regions 34 include the plurality of first contact regions 34A and the plurality of second contact regions 34B.

With reference to FIG. 5 to FIG. 7, the first contact regions 34A are selectively formed on one side of both side surfaces of each trench 17 and are arranged at intervals in the second direction Y. Each first contact region 34A extends along a side wall on one side of each trench 17 from the first principal surface 3 toward the second principal surface 4 in a depth direction of each trench 17 and is electrically connected to the body region 15 and the electric field relaxation structure 21.

In more detail, each first contact region 34A integrally includes a first portion 23, a second portion 24, and a third portion 25 that extend in different directions from each other. Of the plurality of portions of the first contact region 34A, the first portion 23 is a portion extending in the depth direction of the trench 17 (that is, in the vertical direction Z), the second portion 24 is a portion extending in the horizontal direction (in this embodiment, the first direction X) orthogonal to the vertical direction, and the third portion 25 is a portion extending in the horizontal direction (in this embodiment, the first direction X) and toward an opposite side to the second portion 24.

In this embodiment, the first portion 23 of the first contact region 34A extends along the side surface on one side of the trench 17 from the first principal surface 3 toward the second principal surface 4. The first portion 23 is formed in an entirety of the depth direction of the trench 17, from an upper portion to a bottom portion of the trench 17. The first portion 23 has a lower end portion in the vicinity of the bottom portion of the trench 17 and an upper end portion in the vicinity of the upper portion of the trench 17.

The first portion 23 penetrates through the body region 15 and straddles the body region 15 and the electric field relaxation structure 21 which are separated from each other. Of the first portion 23, the second portion 24, and the third portion 25, at least the first portion 23 is formed as a boundary with respect to the body region 15 and is connected to the body region 15. Further, the first portion 23 is also connected to the semiconductor layer 7 (the drift region 8) below the body region 15. That is, between the body region 15 and the electric field relaxation structure 21, a pn junction portion is formed between the first contact region 34A and the drift region 8. The first portion 23 is exposed from the side surface of the trench 17 and is in contact with the insulating film 18 on the side surface of the trench 17. The lower end portion of the first portion 23 may be in contact with the side surface 22 of the electric field relaxation structure 21 instead.

The second portion 24 of the first contact region 34A extends along a bottom surface of the trench 17 from the side surface on the one side of the trench 17 toward an inner side of the trench 17 in a width direction thereof. The second portion 24 penetrates through the side surface 22 of the electric field relaxation structure 21 from the lower end portion of the first portion 23 and is formed on the bottom wall of the trench 17 to width direction intermediate position of the trench 17. In this embodiment, the second portion 24 has, in the horizontal directions, an end portion at a substantially center of the trench 17 in the width direction.

Of the first portion 23, the second portion 24, and the third portion 25, at least the second portion 24 is formed as a boundary with respect to the electric field relaxation structure 21 and is connected to the electric field relaxation structure 21. The second portion 24 is exposed from the bottom surface of the trench 17 and is in contact with the insulating film 18 on the bottom surface of the trench 17. Therefore, on the side surface and the bottom surface of the trench 17, the first contact region 34A having an L-shape in sectional view which is formed by integrating the first portion 23 and the second portion 24 partially covers the embedded electrode 19 via the insulating film 18.

The third portion 25 of the first contact region 34A extends along the first principal surface 3 from the side surface on the one side of the trench 17 toward an outer side of the trench 17 in the width direction (an opposite side to an extending direction of the second portion 24). The third portion 25 is formed on a top wall of the mesa portion 20 from the upper end portion of the first portion 23 to a width direction intermediate position of the mesa portion 20. In this embodiment, the third portion 25 has, in the horizontal directions, an end portion at a substantially center of the mesa portion 20 in the width direction. The third portion 25 is exposed from the first principal surface 3. Therefore, on the side surface and the bottom surface of the trench 17 and the first principal surface 3, the first contact region 34A having a Z-shape in sectional view which is formed by integrating the first portion 23, the second portion 24, and the third portion 25 partially covers the embedded electrode 19 via the insulating film 18 and is exposed for contact from the first principal surface 3.

The first portion 23 has a first thickness T1A. The first thickness T1A may be a thickness of the first portion 23 in the horizontal direction from the side surface of the trench 17. The first thickness T1A may be, for example, not less than 10 nm and not more than 500 nm, and preferably not less than 50 nm and not more than 200 nm.

The second portion 24 has a second thickness T2A. The second thickness T2A may be a thickness of the second portion 24 in the vertical direction Z from the bottom surface of the trench 17. In this embodiment, the second thickness T2A is greater than the first thickness T1A. The second thickness T2A may be, for example, not less than 100 nm and not more than 700 nm, and preferably not less than 200 nm and not more than 500 nm.

The third portion 25 has a third thickness T3A. The third thickness T3A may be a thickness of the third portion 25 in the vertical direction Z from the bottom surface of the trench 17. In this embodiment, the third thickness T3A is greater than the first thickness T1A. The third thickness T3A may be approximately the same as the second thickness T2A. The third thickness T3A may be, for example, not less than 100 nm and not more than 700 nm, and preferably not less than 200 nm and not more than 500 nm.

With reference to FIG. 5, the first portion 23, the second portion 24, and the third portion 25 of the first contact region 34A have an equal width WA in a length direction of the trench 17. The first contact region 34A is thereby formed in a quadrilateral shape (in this embodiment, a rectangular shape) in plan view.

With reference to FIG. 5, FIG. 8, and FIG. 9, the second contact regions 34B are selectively formed on the other side of both the side surfaces of each trench 17 and are arranged at intervals in the second direction Y. Each second contact region 34B extends along a side wall on the other side of each trench 17 from the first principal surface 3 toward the second principal surface 4 in the depth direction of each trench 17 and is electrically connected to the body region 15 and the electric field relaxation structure 21.

In more detail, each second contact region 34B integrally includes a first portion 26, a second portion 27, and a third portion 28 extending in different directions from each other. Of the plurality of portions of the second contact region 34B, the first portion 26 is a portion extending in the depth direction of the trench 17 (that is, in the vertical direction Z), the second portion 27 is a portion extending in the horizontal direction (in this embodiment, the first direction X) orthogonal to the vertical direction, and the third portion 28 is a portion extending in the horizontal direction (in this embodiment, the first direction X) and toward an opposite side to the second portion 27.

In this embodiment, the first portion 26 of the second contact region 34B extends along the side surface on the other side of the trench 17 from the first principal surface 3 toward the second principal surface 4. The first portion 26 is formed in an entirety of the depth direction of the trench 17, from an upper portion to a bottom portion of the trench 17. The first portion 26 has a lower end portion in the vicinity of the bottom portion of the trench 17 and an upper end portion in the vicinity of the upper portion of the trench 17.

The first portion 26 penetrates through the body region 15 and straddles the body region 15 and the electric field relaxation structure 21 which are separated from each other. Of the first portion 26, the second portion 27, and the third portion 28, at least the first portion 26 is formed as a boundary with respect to the body region 15 and is connected to the body region 15. Further, the first portion 26 is also connected to the semiconductor layer 7 (the drift region 8) below the body region 15. That is, between the body region 15 and the electric field relaxation structure 21, a pn junction portion is formed between the second contact region 34B and the drift region 8. The first portion 26 is exposed from the side surface of the trench 17 and is in contact with the insulating film 18 on the side surface of the trench 17. The lower end portion of the first portion 26 may be in contact with the side surface 22 of the electric field relaxation structure 21 instead.

The second portion 27 of the second contact region 34B extends along a bottom surface of the trench 17 from the side surface on the other side of the trench 17 toward an inner side of the trench 17 in a width direction thereof. The second portion 27 penetrates through the side surface 22 of the electric field relaxation structure 21 from the lower end portion of the first portion 26 and is formed on the bottom wall of the trench 17 to a width direction intermediate position of the trench 17. In this embodiment, the second portion 27 has, in the horizontal directions, an end portion at a substantially center of the trench 17 in the width direction.

Of the first portion 26, the second portion 27, and the third portion 28, at least the second portion 27 is formed as a boundary with respect to the electric field relaxation structure 21 and is connected to the electric field relaxation structure 21. The second portion 27 is exposed from the bottom surface of the trench 17 and is in contact with the insulating film 18 on the bottom surface of the trench 17. Therefore, on the side surface and the bottom surface of the trench 17, the second contact region 34B having an L-shape in sectional view which is formed by integrating the first portion 26 and the second portion 27 partially covers the embedded electrode 19 via the insulating film 18.

The third portion 28 of the second contact region 34B extends along the first principal surface 3 from the side surface on the other side of the trench 17 toward an outer side of the trench 17 in the width direction (an opposite side to an extending direction of the second portion 27). The third portion 28 is formed on a top wall of the mesa portion 20 from the upper end portion of the first portion 26 to a width direction intermediate position of the mesa portion 20. In this embodiment, the third portion 28 has, in the horizontal directions, an end portion at a substantially center of the mesa portion 20 in the width direction. The third portion 28 is exposed from the first principal surface 3. Therefore, on the side surface and the bottom surface of the trench 17 and the first principal surface 3, the second contact region 34B having a Z-shape in sectional view which is formed by integrating the first portion 26, the second portion 27, and the third portion 28 partially covers the embedded electrode 19 via the insulating film 18 and is exposed for contact from the first principal surface 3.

The first portion 26 has a first thickness T1B. The first thickness T1B may be a thickness of the first portion 26 in the horizontal direction from the side surface of the trench 17. The first thickness T1B may be, for example, not less than 10 nm and not more than 500 nm, and preferably not less than 50 nm and not more than 200 nm.

The second portion 27 has a second thickness T2B. The second thickness T2B may be a thickness of the second portion 27 in the vertical direction Z from the bottom surface of the trench 17. In this embodiment, the second thickness T2B is greater than the first thickness T1B. The second thickness T2B may be, for example, not less than 100 nm and not more than 700 nm, and preferably not less than 200 nm and not more than 500 nm.

The third portion 28 has a third thickness T3B. The third thickness T3B may be a thickness of the third portion 28 in the vertical direction Z from the bottom surface of the trench 17. In this embodiment, the third thickness T3B is greater than the first thickness T1B. The third thickness T3B may be approximately the same as the second thickness T2B. The third thickness T3B may be, for example, not less than 100 nm and not more than 700 nm, and preferably not less than 200 nm and not more than 500 nm.

With reference to FIG. 5, the first portion 26, the second portion 27, and the third portion 28 of the second contact region 34B have an equal width WB in the length direction of the trench 17. The second contact region 34B is thereby formed in a quadrilateral shape (in this embodiment, a rectangular shape) in plan view.

With reference to FIG. 5, the first contact regions 34A and the second contact regions 34B are arranged at intervals in the length direction of the trench 17. In this embodiment, the plurality of first contact regions 34A are uniformly located, throughout the plurality of trenches 17, on the one side of each trench 17 in the width direction. The plurality of second contact regions 34B are uniformly located, throughout the plurality of trenches 17, on the other side in the width direction of each trench 17. In other words, the plurality of first contact regions 34A are formed on the one side in the width direction of all of the trenches 17 and the plurality of second contact regions 34B are formed on the other side.

In this embodiment, in each mesa portion 20, the first contact regions 34A and the second contact regions 34B are arranged alternately on the left and right at intervals. In other words, of a pair of trenches 17A, 17B among the plurality of trenches 17, at positions adjacent in the first direction X (the width direction of the trenches 17) with respect to regions 29 between the plurality of first contact regions 34A of the one trench 17A, the second contact regions 34B of the other trench 17B are located. Also, at positions adjacent in the first direction X (the width direction of the trenches 17) with respect to regions 30 between the plurality of second contact regions 34B of the other trench 17B, the first contact regions 34A of the other trench 17B are located. The first contact regions 34A and the second contact regions 34B are thereby arranged in a zigzag pattern as a whole in plan view.

In each mesa portion 20, the body region 15 includes a channel portion 31 and a non-channel portion 32. The channel portion 31 is a region in which the plurality of contact regions 34A and 34B are not formed in the body region 15. In this embodiment, the regions 29 and the regions 30 are the channel portions 31. A channel is formed along a wall surface of the trench 17 adjacent to the channel portion 31. In the non-channel portions 32, the wall surfaces of the trenches 17 adjacent thereto are covered with the contact regions 34A and 34B from the upper portions to the bottom portions of the trenches 17.

The semiconductor device 1 includes source regions 33 that are formed in regions between the plurality of trench structures 16 in the surface layer portion of the first principal surface 3 (the active surface 11). The source region 33 as an example of a third impurity region is formed in the surface layer portion of body region 15. In this embodiment, the source regions 33 are formed, in the mesa portion 20, in regions in which the plurality of contact regions 34A and 34B are not formed. As described above, in each mesa portion 20, the first contact regions 34A and the second contact regions 34B are arranged alternately on the left and right at intervals in the length direction of the trenches 17. The regions in which the source regions 33 are formed in the body region 15 are the channel portions 31 described above. As shown in FIG. 5, the source region 33 passes between the plurality of first contact regions 34A and the plurality of second contact regions 34B that are arranged alternately on the left and right and is formed in a zigzag shape in the second direction Y.

A plurality of first channel sections 35 and a plurality of second channel sections 36 are thereby arranged alternately in the second direction Y (the length direction of the trench 17) in each mesa portion 20. The first channel section 35 is the channel portion 31 corresponding to the region 29 and the second channel section 36 is the channel portion 31 corresponding to the region 30. The first channel section 35 and the second channel section 36 may have an overlap channel section 49 overlapping in the first direction X. In the overlap channel section 49, channels are formed on each of the wall surfaces of the trench 17 on both sides of the mesa portion 20 in the first direction X.

The source regions 33 have an n-type impurity concentration (a peak value) higher than the semiconductor layer 7. The source regions 33 may have an n-type impurity concentration of not less than 1×10¹⁸ cm⁻³ and not more than 1×10²¹ cm⁻³ as a peak value.

The source regions 33 are formed at intervals to the active surface 11 side from the bottom portion of the body region 15 and face the drift region 8 directly below the body region 15 with portions of the body region 15 interposed therebetween in the vertical direction Z. The plurality of source regions 33, together with the plurality of drift regions 8 directly below, demarcate channels (current paths) that extend along the wall surfaces of the corresponding trench structures 16.

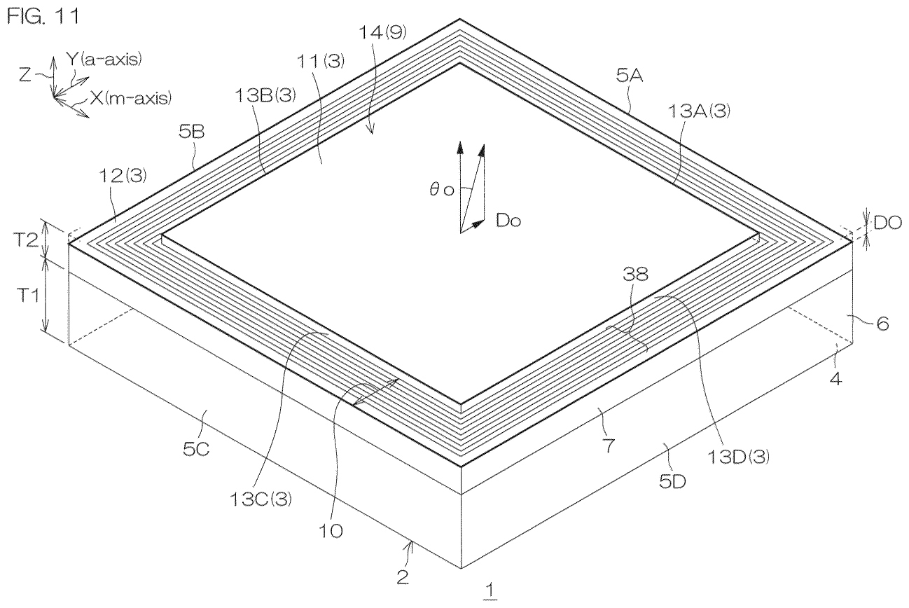

Hereinafter, an arrangement on the outer peripheral region 10 side will be described. FIG. 11 is a perspective view showing an arrangement of the outer peripheral region 10. FIG. 12 is a sectional view showing a principal portion of the outer peripheral region 10.

The semiconductor device 1 includes a well region 37 of the p-type formed in a surface layer portion of the outer surface 12. In plan view, the well region 37 is formed at intervals to the active surface 11 side from the peripheral edges of the outer surface 12 (from the first to fourth side surfaces 5A to 5D) and extends in a band shape along the active surface 11. In this embodiment, the well region 37 is formed in an annular shape (specifically, a quadrilateral annular shape) surrounding the active surface 11 in plan view.

The well region 37 is led out from the surface layer portion of the outer surface 12 to the first to fourth connecting surfaces 13A to 13D sides and extends along surface layer portions of the first to fourth connecting surfaces 13A to 13D. The well region 37 is electrically connected to the body region 15 in the surface layer portion of the active surface 11.

The well region 37 is formed at an interval to the outer surface 12 side from the lower end of the semiconductor layer 7 and faces the base layer 6 with a portion of the semiconductor layer 7 interposed therebetween. The well region 37 forms a pn junction portion with the semiconductor region 7. The well region 37 may have a p-type impurity concentration of not less than 1×10¹⁵ cm⁻³ and not more than 1×10¹⁸ cm⁻³ as a peak value. The well region 37 has a p-type impurity concentration lower than the p-type impurity concentration of the plurality of contact regions 34A and 34B.

The p-type impurity concentration of the well region 37 may be higher than the p-type impurity concentration of the body region 15. As a matter of course, the p-type impurity concentration of the well region 37 may be lower than that of the body regions 15. The p-type impurity concentration of the well region 37 is preferably adjusted by at least one type of trivalent element. The trivalent element of the well region 37 may be the same type as a trivalent element of the electric field relaxation structure 21, or may be a type different from the trivalent element of the electric field relaxation structure 21. The trivalent element of the well region 37 may be at least one type among boron, aluminum, gallium, and indium.

The semiconductor device 1 includes at least one (preferably not less than two and not more than twenty) of field regions 38 of the p-type formed in the surface layer portion of the outer surface 12 (the first principal surface 3) in the outer peripheral region 10. The number of the plurality of the field regions 38 is typically not less than 4 and not more than 8. The plurality of field regions 38 are formed in an electrically floating state and relax an electric field inside the chip 2 at peripheral edge portions of the first principal surface 3. The number, width, depth, p-type impurity concentration, etc., of the field regions 38 are arbitrary and can take on any of various values in accordance with the electric field to be relaxed.

In this embodiment, the plurality of field regions 38 are arranged at intervals from the peripheral edges of the active surface 11 (from the first to fourth connecting surfaces 13A to 13D) and from the peripheral edges (the first to fourth side surfaces 5A to 5D) of the chip 2. Specifically, the plurality of field regions 38 are arranged at intervals to the peripheral edge sides of the outer surface 12 from the well region 37.

The plurality of field regions 38 are formed in band shapes extending along the active region 9 in plan view. The plurality of field regions 38 each have portions extending in a band shape in the first direction X and portions extending in a band shape in the second direction Y. In this embodiment, the plurality of field regions 38 are formed in annular shapes (specifically, quadrilateral annular shapes) surrounding the active region 9 (that is, the plurality of column regions 21) in plan view.

The plurality of field regions 38 are formed inside the semiconductor layer 7 at intervals to the outer surface 12 side from the lower end of the semiconductor layer 7 and form pn junction portions with the semiconductor layer 7. The plurality of field regions 38 preferably have bottom portions positioned at the outer surface 12 side with respect to an intermediate portion of the semiconductor layer 7 in a thickness range thereof.

In this embodiment, the plurality of field regions 38 are formed at intervals to the peripheral edge side of the chip 2 from the electric field relaxation structures 21. Therefore, the plurality of field regions 38 do not face the electric field relaxation structures 21 in the vertical direction Z. The plurality of field regions 38 are positioned further to the second principal surface 4 side of the semiconductor layer 7 than the bottom walls of the trench structures 16.

The bottom portions of the plurality of field regions 38 may be positioned further to the first principal surface 3 side of the semiconductor layer 7 than depth positions of bottom portions of the plurality of electric field relaxation structures 21. As a matter of course, the bottom portions of the plurality of field regions 38 may be positioned further to the second principal surface 4 side of the semiconductor layer 7 than the depth positions of the bottom portions of the electric field relaxation structures 21 instead.

The plurality of field regions 38 may have a p-type impurity concentration of not less than 1×10¹⁵ cm⁻³ and not more than 1×10¹⁸ cm⁻³ as a peak value. The p-type impurity concentration of the field region 38 may be substantially equal to the p-type impurity concentration of the body region 15. The p-type impurity concentration of the plurality of field regions 38 may be higher than the p-type impurity concentration of the body region 15. The p-type impurity concentration of the plurality of field regions 38 may be lower than the p-type impurity concentration of the body region 15.

The p-type impurity concentration of the plurality of field regions 38 is preferably adjusted by at least one type of trivalent element. The trivalent element of the field region 38 may be the same type as the trivalent element of the electric field relaxation structure 21, or may be a type different from the trivalent element of the electric field relaxation structure 21. The trivalent element of the field region 38 may be at least one type among boron, aluminum, gallium, and indium.

The plurality of field regions 38 preferably have a width different from the relaxation width WR of the electric field relaxation structures 21. That is, an electric field relaxation effect by the field regions 38 is preferably adjusted separately from the plurality of electric field relaxation structures 21. The width of the plurality of field regions 38 is particularly preferably smaller than the relaxation width WR As a matter of course, the width of the plurality of field regions 38 may be larger than the relaxation width WR. Also, the width of the plurality of field regions 38 may be substantially equal to the relaxation width WR

The plurality of field regions 38 are preferably formed at a pitch different from the relaxation pitch PR of the electric field relaxation structures 21. The pitch of the plurality of field regions 38 is particularly preferably smaller than the relaxation pitch PR. The pitch of the plurality of field regions 38 may be larger than the relaxation pitch PR. The pitch of the plurality of field regions 38 may be substantially equal to the relaxation pitch PR.

The semiconductor device 1 includes an interlayer insulating film 39 that covers the first principal surface 3. The interlayer insulating film 39 may be referred to as an “insulating film,” an “interlayer film,” an “intermediate insulating film,” etc. In this embodiment, the interlayer insulating film 39 has a laminated structure including a first insulating film 40 and a second insulating film 41. The first insulating film 40 may include at least one among a silicon oxide film, a silicon nitride film, and a silicon oxynitride film. The first insulating film 40 particularly preferably includes the silicon oxide film constituted of the oxide of the chip 2 (the semiconductor layer 7).

The first insulating film 40 selectively covers the first principal surface 3 in the active region 9 and the outer peripheral region 10. Specifically, the first insulating film 40 selectively covers the active surface 11, the outer surface 12, and the first to fourth connecting surfaces 13A to 13D. On the active surface 11, first insulating film 40 is connected to the insulating film 18 on the active surface and exposes the embedded electrode 19.

On the outer surface 12, the first insulating film 40 covers the well region 37 and the plurality of field regions 38. In this embodiment, the first insulating film 40 is continuous to the first to fourth side surfaces 5A to 5D. As a matter of course, the first insulating film 40 may instead be formed at intervals inward from the peripheral edges of the outer surface 12 and expose the semiconductor layer 7 from peripheral edge portions of the outer surface 12. On the first to fourth connecting surfaces 13A to 13D, the first insulating film 40 covers the body region 15 and the well region 37.

The second insulating film 41 is laminated on the first insulating film 40. The second insulating film 41 may include at least one among a silicon oxide film, a silicon nitride film, and a silicon oxynitride film. The interlayer insulating film 39 preferably includes a silicon oxide film. The second insulating film 41 covers the first principal surface 3 with the first insulating film 40 interposed therebetween in the active region 9 and the outer peripheral region 10. Specifically, the second insulating film 41 selectively covers the active surface 11, the outer surface 12, and the first to fourth connecting surfaces 13A to 13D with the first insulating film 40 interposed therebetween.

In the active region 9, the second insulating film 41 covers the plurality of trench structures 16 (the embedded electrodes 19). In the outer peripheral region 10, the second insulating film 41 covers the well region 37 and the plurality of field regions 38 with the first insulating film 40 interposed therebetween. In this embodiment, the second insulating film 41 is continuous to the first to fourth side surfaces 5A to 5D. As a matter of course, the second insulating film 41 may instead be formed at intervals inward from the peripheral edges of the outer surface 12 and, together with the first insulating film 40, expose the peripheral edge portions of the first principal surface 3.

The semiconductor device 1 includes a plurality of contact openings 42 formed in the interlayer insulating film 39. The plurality of contact openings 42 include the plurality of contact openings 42 (not shown) that expose the plurality of trench structures 16 (the embedded electrodes 19) and the plurality of contact openings 42 that expose the plurality of source regions 33. The plurality of contact openings 42 for the source regions 33 are formed in regions between the plurality of trench structures 16 that are mutually adjacent and expose the plurality of source regions 33 and the plurality of contact regions 34.

The semiconductor device 1 includes a side wall structure 43 that is arranged in the interlayer insulating film 39 such as to cover at least one of the first to fourth connecting surfaces 13A to 13D. The side wall structure 43 is arranged on the first insulating film 40 and is covered with the second insulating film 41. The side wall structure 43 moderates a level difference formed between the active surface 11 and the outer surface 12.

The side wall structure 43 is formed in a band shape extending along at least one of the first to fourth connecting surfaces 13A to 13D. In this embodiment, the side wall structure 43 is formed in an annular shape (specifically, a quadrilateral annular shape) extending along the first to fourth connecting surfaces 13A to 13D such as to surround the active surface 11 in plan view.

The side wall structure 43 may have a portion extending in a film shape along the outer surface 12 and a portion extending in a film shape along the first to fourth connecting surfaces 13A to 13D. In this embodiment, the side wall structure 43 is formed at an interval from the innermost field region 38 toward the active surface 11 and faces the well region 37 with the first insulating film 40 interposed therebetween in the horizontal directions and the vertical direction Z. The side wall structure 43 may face the body region 15 with the first insulating film 40 interposed therebetween.

With reference to FIG. 1, the semiconductor device 1 includes a gate pad 44 arranged on the interlayer insulating film 39. The gate pad 44 is an electrode to which the gate potential is applied from an exterior. The gate pad 44 may be referred to as a “gate pad electrode,” a “first pad electrode,” etc. The gate pad 44 may have a laminated structure that includes a Ti-based metal film and an Al-based metal film that are laminated in that order from the interlayer insulating film 39 side.

In this embodiment, the gate pad 44 is arranged on a portion of the interlayer insulating film 39 that covers the active region 9. Specifically, the gate pad 44 is arranged on the active surface 11 at an interval from the outer surface 12 in plan view. The gate pad 44 is arranged in a region adjacent to a central portion of one side (in this embodiment, the second connecting surface 13B) of the active surface 11 in plan view.

As a matter of course, the gate pad 44 may be arranged in a region along any of central portions of the first to fourth connecting surfaces 13A to 13D. As a matter of course, the gate pad 44 may be arranged in an arbitrary corner portion of the active surface 11 in plan view. Also, the gate pad 44 may be arranged at a central portion of the active surface 11 in plan view. In this embodiment, the gate pad 44 is formed in a quadrilateral shape in plan view.

The semiconductor device 1 includes at least one (in this embodiment, a plurality) of gate wirings 45 that is led out onto the interlayer insulating film 39 from the gate pad 44. The gate wiring 45 may be referred to as a “wiring,” a “wiring electrode,” etc. In this embodiment, the plurality of gate wirings 45 are arranged on the active surface 11 at intervals from the outer surface 12 in plan view.

The plurality of gate wirings 45 may have a laminated structure that includes a Ti-based metal film and an Al-based metal film that are laminated in that order from the interlayer insulating film 39 side. In this embodiment, the plurality of gate wirings 45 include a first gate wiring 45A and a second gate wiring 45B.

The first gate wiring 45A is led out toward the first connecting surface 13A side from the gate pad 44 and extends in a line shape along the peripheral edge of the active surface 11 such as to intersect (specifically, be orthogonal to) portions (specifically, one end portions) of the plurality of trench structures 16. The first gate wiring 45A penetrates through the interlayer insulating film 39 via the plurality of contact openings 42 and is electrically connected to the one end portions of the plurality of trench structures 16.

The second gate wiring 45B is led out toward the third connecting surface 13C side from the gate pad 44 and extends in a line shape along the peripheral edge of the active surface 11 such as to intersect (specifically, be orthogonal to) portions (specifically, the other end portions) of the plurality of trench structures 16. The second gate wiring 45B penetrates through the interlayer insulating film 39 via the plurality of contact openings 42 and is electrically connected to the other end portions of the plurality of trench structures 16.

The semiconductor device 1 includes a source pad 46 arranged on the interlayer insulating film 39 at intervals from the gate pad 44 and the gate wirings 45. The source pad 46 is an electrode to which a source potential is applied from an exterior. The source pad 46 may be referred to as a “source pad electrode,” a “second pad electrode,” etc. The source pad 46 may have a laminated structure that includes a Ti-based metal film and an Al-based metal film that are laminated in that order from the interlayer insulating film 39 side.

In this embodiment, the source pad 46 is arranged on the active surface 11 at an interval from the outer surface 12 in plan view. In this embodiment, the source pad 46 is formed in a polygonal shape having a recess portion that is recessed along the gate pad 44 in plan view. As a matter of course, the source pad 46 may instead be formed in a quadrilateral shape in plan view.

The source pad 46 penetrates through the interlayer insulating film 39 via the plurality of contact openings 42 and is electrically connected to the body region 15, the plurality of source regions 33, and the plurality of contact regions 34A and 34B. That is, the source pad 46 is electrically connected to the plurality of electric field relaxation structures 21 via the body region 15 and the plurality of contact regions 34A and 34B.

The semiconductor device 1 includes a drain pad 47 that covers the second principal surface 4. The drain pad 47 is an electrode to which a drain potential is applied from an exterior. The drain pad 47 may be referred to as a “drain pad electrode,” a “third pad electrode,” etc. The drain pad 47 forms an ohmic contact with the base layer 6 exposed from the second principal surface 4.

That is, the drain pad 47 is electrically connected to the plurality of drift regions 8 via the base layer 6. The drain pad 47 may cover an entirety of the second principal surface 4 such as to be continuous to the peripheral edges (the first to fourth side surfaces 5A to 5D) of the chip 2. The drain pad 47 may cover the second principal surface 4 at intervals inward from the peripheral edges of the chip 2 such as to expose the peripheral edge portions of the chip 2.

A breakdown voltage applicable between the source pad 46 and the drain pad 47 (between the first principal surface 3 and the second principal surface 4) may be not less than 500 V and not more than 3000 V. The breakdown voltage may have a value belonging to any one range among not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

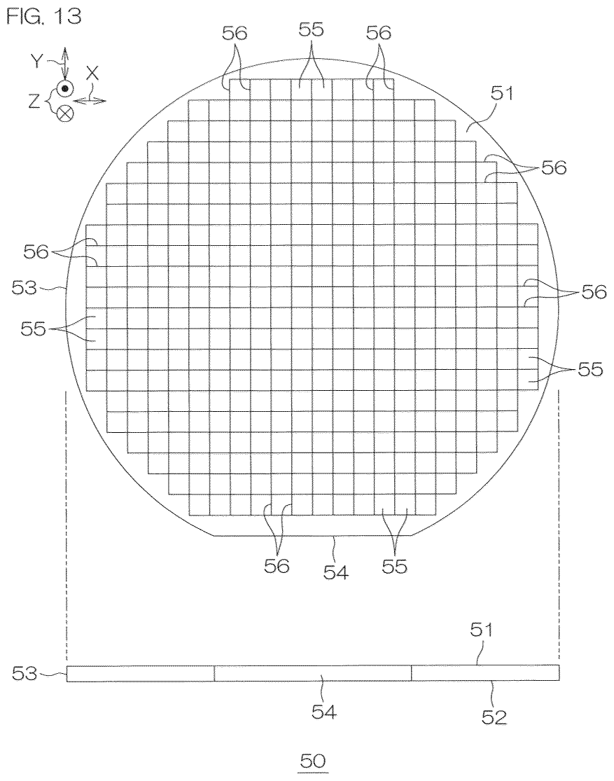

FIG. 13 is a schematic view showing a wafer 50 used in manufacture of the semiconductor device 1. The wafer 50 is a base material of the base layer 6 and contains an SiC monocrystal. The wafer 50 is formed in a flat disk shape. As a matter of course, the wafer 50 may be formed in a flat rectangular parallelepiped shape instead. The wafer 50 has a first wafer principal surface 51 on one side, a second wafer principal surface 52 on the other side, and a wafer side surface 53 connecting the first wafer principal surface 51 and the second wafer principal surface 52.

The first wafer principal surface 51 corresponds to the upper end of the base layer 6, and the second wafer principal surface 52 corresponds to a lower end of the base layer 6. The first wafer principal surface 51 and the second wafer principal surface 52 are formed by c-planes of the SiC monocrystal. The first wafer principal surface 51 is formed by a silicon plane of the SiC monocrystal, and the second wafer principal surface 52 is formed by a carbon plane of the SiC monocrystal. The wafer 50 (the first wafer principal surface 51 and the second wafer principal surface 52) has the off direction Do and the off angle θo described above.

The wafer 50 has, on the wafer side surface 53, a mark 54 that indicates a crystal orientation of the SiC monocrystal. The mark 54 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 51 in plan view.

The mark 54 may include either or both of a first orientation flat that extends in the m-axis direction and a second orientation flat that extends in the a-axis direction. The mark 54 may include either or both of an orientation notch that is recessed in the m-axis direction and an orientation notch flat that is recessed in the a-axis direction. In FIG. 12, the orientation flat that extends in the m-axis direction (the first direction X) in plan view is shown.

For example, a plurality of device regions 55 and a plurality of intended cutting lines 56 are set by alignment marks, etc., in the wafer 50. Each device region 55 is a region corresponding to the semiconductor device 1. The plurality of device regions 55 are each set in a quadrilateral shape in plan view.

In this embodiment, the plurality of device regions 55 are set in a matrix along the first direction X and the second direction Y. The plurality of device regions 55 are each set at intervals inward from a peripheral edge of the first wafer principal surface 51 in plan view. The plurality of intended cutting lines 56 are set in a lattice extending along the first direction X and the second direction Y such as to demarcate the plurality of device regions 55.

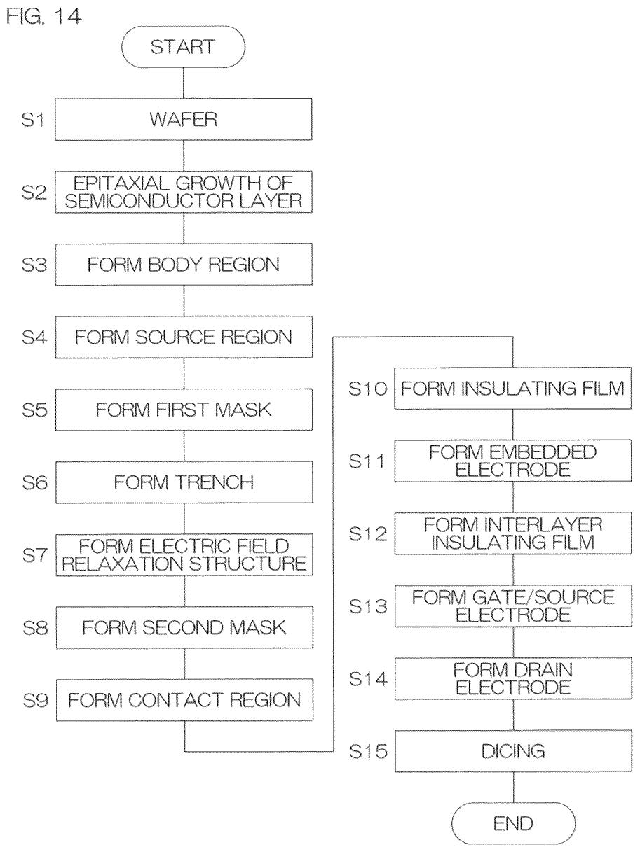

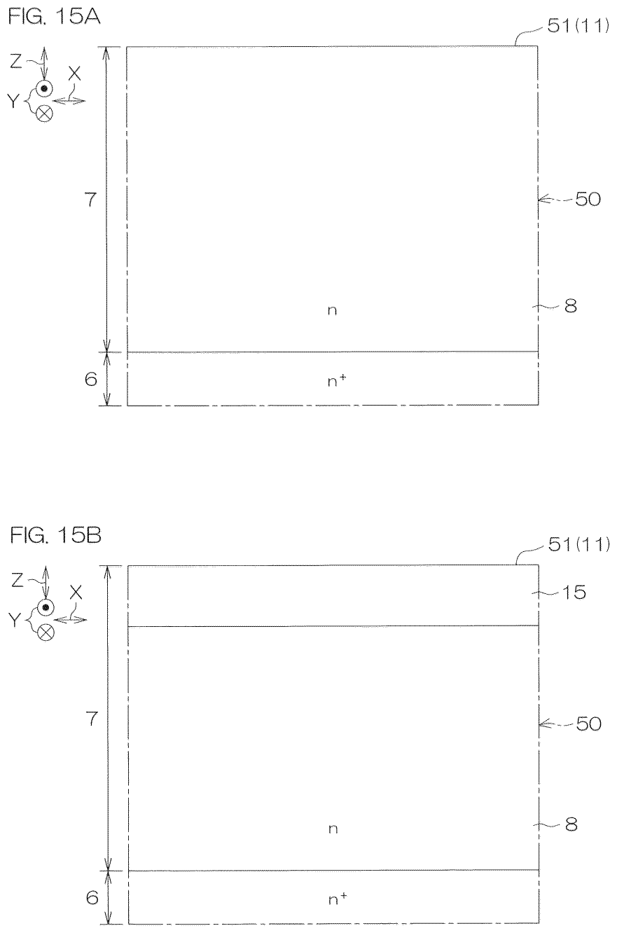

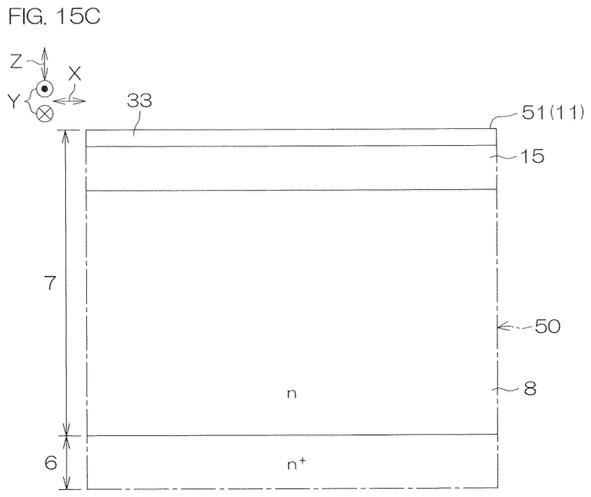

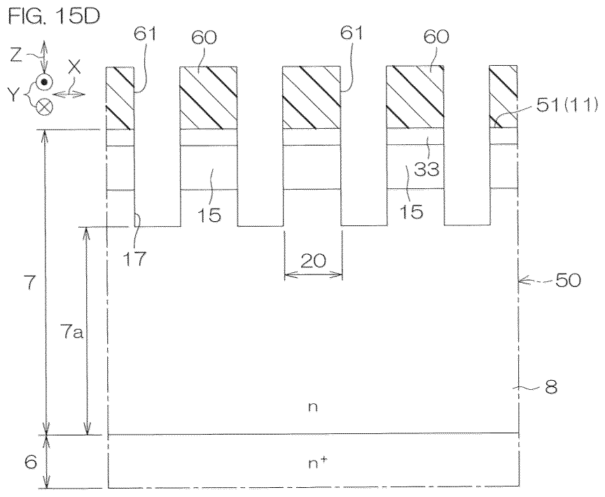

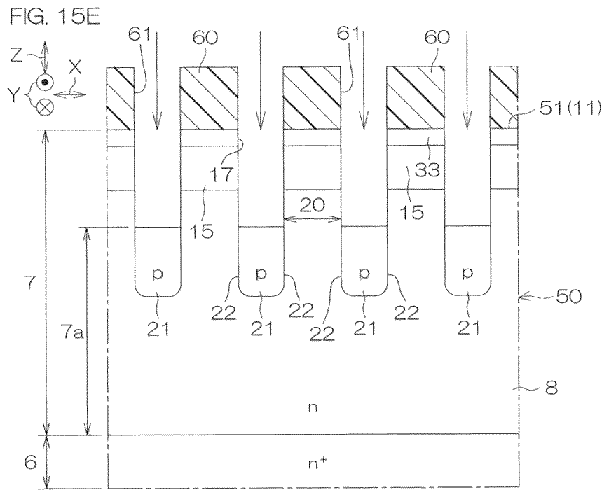

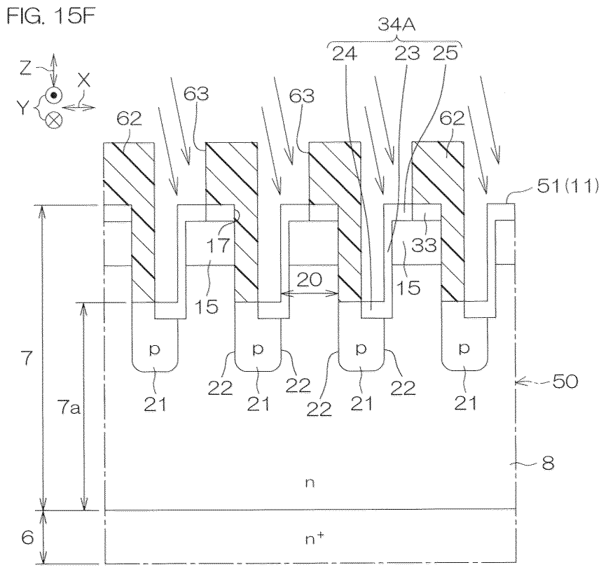

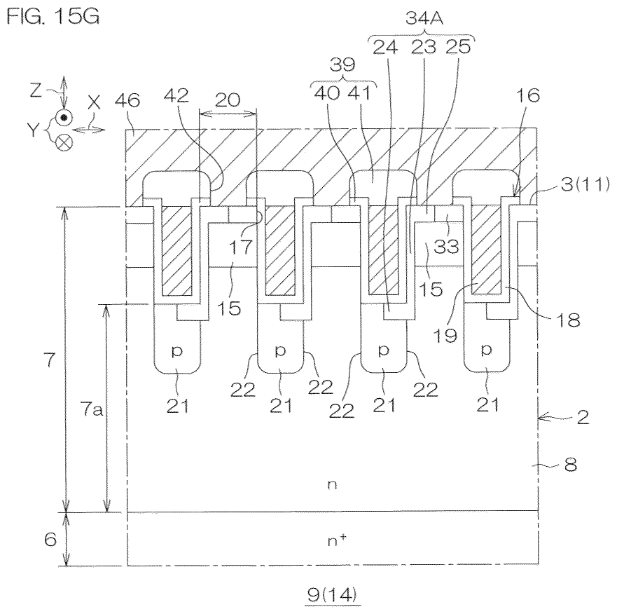

FIG. 14 is a flowchart showing a manufacturing method example of the semiconductor device 1. FIG. 15A to FIG. 15G are sectional views showing the manufacturing method example of the semiconductor device 1. FIG. 15A to FIG. 15G are sectional views corresponding to FIG. 6.

First, with reference to FIG. 15A, a preparation step of the wafer 50 described above is performed (step S1 in FIG. 14). Next, a forming step of the semiconductor layer 7 is performed (step S2 of FIG. 14). The semiconductor layer 7 is formed by an epitaxial growth method with the first wafer principal surface 51 (the wafer 50) as a starting point.

Next, with reference to FIG. 15B, a forming step of the body region 15 is performed (step S3 of FIG. 14). In the forming step of the body region 15, a p-type impurity is introduced into an entirety of the semiconductor layer 7. The body region 15 are thereby be formed in an entirety of the surface layer portion of the semiconductor layer 7.

Next, with reference to FIG. 15C, a forming step of the source regions 33 is performed (step S4 of FIG. 14). In the forming step of the source regions 33, an n-type impurity is selectively introduced into the semiconductor layer 7 (the surface layer portion of the body region 15). The source regions 33 are thereby formed in the surface layer portion of the body region 15.

Next, with reference to FIG. 15D, a forming step of the plurality of trenches 17 is performed. First, a first mask 60 having a predetermined pattern is formed (step S5 in FIG. 14). The first mask 60 is preferably an inorganic mask (a hard mask). The first mask 60 has a plurality of first openings 61 that expose regions at which the plurality of trenches 17 are to be formed. Next, unnecessary portions of the semiconductor layer 7 are removed by an etching method via the first mask 60. The etching method may be either or both of a wet etching method and a dry etching method. The etching method is preferably an RIE (reactive ion etching) method. The plurality of trenches 17 are thereby formed in the upper end of the semiconductor layer 7 (step S6 in FIG. 14). Also, the active surface 11, the outer surface 12, and the first to fourth connecting surfaces 13A to 13D are formed at the upper end of the semiconductor layer 7.

Next, with reference to FIG. 15E, a forming step of the plurality of electric field relaxation structures 21 is performed, with the first mask 60 left on the semiconductor layer 7 (step S7 in FIG. 14). In the forming step of the electric field relaxation structures 21, the p-type impurity is selectively introduced into the semiconductor layer 7 via the first mask 60. The electric field relaxation structure 21 is thereby formed in the bottom portion of each trench 17.

As a forming method of the electric field relaxation structures 21, various ion implantation methods can be applied. For example, the electric field relaxation structures 21 may be formed by a channeling ion implantation method. The channeling implantation step is performed based on the data (the information) on the off angle θo. In the channeling implantation step, the electric field relaxation structures 21 can be selectively and easily formed at a deep position of the semiconductor layer 7. In a case where the electric field relaxation structures 21 are formed by the channeling ion implantation method, the electric field relaxation structures 21 may be formed before the body region 15 is formed. Thereafter, the first mask 60 is removed.

Next, with reference to FIG. 15F, a forming step of the plurality of contact regions 34A and 34B is performed. First, a second mask 62 having a predetermined pattern is formed (step S8 in FIG. 14). The second mask 62 is preferably an inorganic mask (a hard mask). The second mask 62 has a plurality of second openings 63 that expose regions at which the plurality of contact regions 34A and 34B are to be formed.

Next, the plurality of contact regions 34A and 34B are formed by introducing a p-type impurity into the surface layer portion of the semiconductor layer 7 by an ion implantation method via the second mask 62. In this embodiment, oblique implantation is performed at a predetermined angle with respect to the first wafer principal surface 51. Ion implantation into the side surface of the trench 17 can thereby be performed in addition to the first wafer principal surface 51 and the bottom portion of the trench 17. On the other hand, as described above, the trench structures 16 have an aspect ratio DT/WT (for example, not less than 1 and not more than 5) of extending in a vertically long columnar shape and the trench depth DT is much greater than the trench width WT. Therefore, it is necessary to increase an implantation angle in order to perform ion implantation uniformly on the entire side surface of the trench 17. As a result, an ion implantation is performed to a shallow depth from the side surface of the trench 17, and in the obtained plurality of contact regions 34A and 34B, the second thickness T2A<the first thickness T1A, the third thickness T3A, and the second thickness T2B<the first thickness T1B and the third thickness T3B.

Next, with reference to FIG. 15G, a forming step of the insulating films 18 is performed (step S10 in FIG. 14). The forming step of the insulating films 18 serves in common as a forming step of the first insulating film 40. The insulating films 18 may be formed by either or both of a CVD (chemical vapor deposition) method and an oxidation treatment method. The insulating films 18 and the first insulating film 40 are typically formed by a thermal oxidation treatment method. The insulating films 18 are formed in a film shape on the wall surfaces of the plurality of trenches 17, and the first insulating film 40 is formed in a film shape in a region of the upper end of the semiconductor layer 7 outside the plurality of trenches 17.

Next, a forming step of the embedded electrodes 19 is performed (step S11 in FIG. 14). This step includes a step of forming a base electrode film on the insulating films 18. In this embodiment, the base electrode film contains a conductive polysilicon. The base electrode film backfills the plurality of trenches 17 and covers the upper end of the semiconductor layer 7. The base electrode film may be formed by the CVD method. Next, unnecessary portions of the embedded electrodes 19 are removed by the etching method. The unnecessary portions of the embedded electrodes 19 are removed until the insulating films 18 are exposed. The etching method may be either or both of a wet etching method and a dry etching method. Thereby, the plurality of embedded electrodes 19 are respectively embedded inside the plurality of trenches 17 and the plurality of trench structures 16 are formed.

Next, a forming step of the interlayer insulating film 39 (the second insulating film 41) is performed (step S12 in FIG. 14). The interlayer insulating film 39 may be formed by the CVD method. The plurality of contact openings 42 having a predetermined layout are formed in the interlayer insulating film 39 by an etching method performed via a mask (not shown) having the predetermined layout.

Next, a forming step of the gate pad 44, the gate wiring 45, and the source pad 46 is performed (step S13 in FIG. 14) The gate pad 44, the gate wirings 45, and the source pad 46 are formed by depositing a metal film on the interlayer insulating film 39 by the sputtering method and thereafter forming to a predetermined layout by the etching method performed via a mask (not shown) having the predetermined layout.

Next, a forming step of the drain pad 47 is performed (step S14 in FIG. 14). The drain pad 47 is formed by depositing a metal film on the second wafer principal surface 52 by the sputtering method. Thereafter, the wafer 50 is cut along the plurality of intended cutting lines 56 (step S15 in FIG. 14). Through steps including the above, a plurality of semiconductor devices 1 are manufactured from the single wafer 50.

As described above, since the electric field relaxation structure 21 is formed on the bottom wall of the trench 17, it is possible to relax concentration of electric fields on the bottom wall of the trench 17 of the trench gate structure according to the MISFET (metal insulator semiconductor field effect transistor). Also, since the electric field relaxation structures 21 are connected to the plurality of contact regions 34A and 34B, the electric field relaxation structures 21 can be fixed at a predetermined potential (in this embodiment, the source potential) via the plurality of contact regions 34A and 34B. For example, it is possible to stabilize and relax the concentration of electric fields on the bottom wall of the trench 17 by setting the source potential to a ground potential.

Also, the plurality of contact regions 34A and 34B for contact with the electric field relaxation structures 21 are separately located on the one side and the other side of each trench 17 in the width direction. In this embodiment, the first contact regions 34A and the second contact regions 34B are arranged alternately on the left and right at intervals in the length direction of the trenches 17 of the respective mesa portions 20. The source regions 33 are thereby formed in the zigzag shape in the second direction Y and the plurality of first channel sections 35 and the plurality of second channel sections 36 are alternately arranged in the second direction Y (the length direction of the trench 17). As a result, since the channels can be uniformly formed in the length direction of the trenches 17, the current balance at the time of short circuit can be made uniform. Thus, local current concentration on the mesa portion 20 can be prevented and the breakdown resistance can be improved.

For example, in an embodiment in which the contact regions 34A are selectively formed just on one side of each trench 17 in the width direction, a channel current flows just on the other side of each trench 17 in the width direction. Therefore, the current concentrates on the other side of each trench 17 in the width direction and there are more cases where breakdown occurs at the time of short circuit. On the other hand, in the embodiment described above, since the channels can be uniformly formed in a balanced manner in the length direction of the trenches 17, it is possible to prevent the current concentration and improve the breakdown resistance.

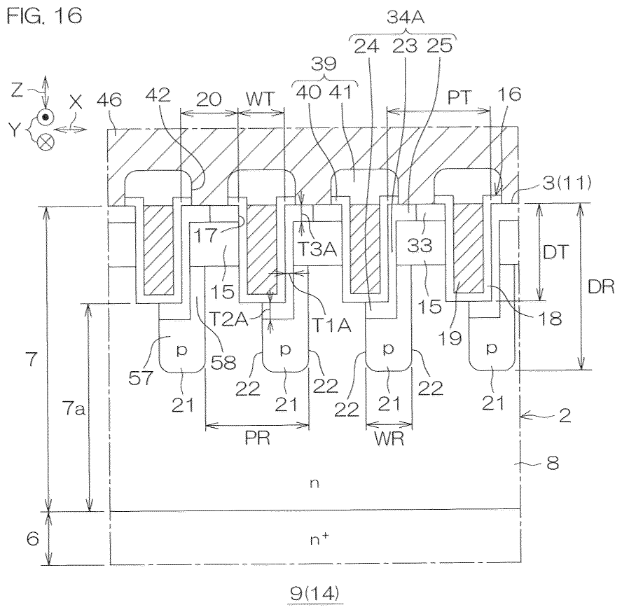

FIG. 16 to FIG. 22 are views showing first to sixth modification examples of the semiconductor device 1. Next, the modification examples of the semiconductor device 1 shall be described with reference to FIG. 16 to FIG. 22.

With reference to FIG. 16, the side surfaces 22 of the plurality of electric field relaxation structures 21 may be positioned at the center of the trench 17 in the width direction. In more detail, the individual electric field relaxation structures 21 are formed integrally with the body region 15 and are formed on one side in the first direction X with respect to the trench 17. In this embodiment, each electric field relaxation structure 21 extends more downwardly than the bottom wall of the trench 17 in the vertical direction Z from a portion of the body region 15 sandwiched between the two trenches 17 that are mutually adjacent, widens along the horizontal directions oriented along the first principal surface 3, and overlaps the bottom wall of the trench 17. Each electric field relaxation structure 21 thereby has, inside each trench 17, a substantially L-shaped exposed surface that is exposed as a lower portion of the side wall of the corresponding trench 17 and the bottom wall of the corresponding trench 17 which continues to the lower portion of the side wall.

The electric field relaxation structure 21 may integrally include a base portion 57 further to the second principal surface 4 side than the bottom wall of the trench 17, and a protrusion portion 58 sandwiched between the two trenches 17 that are mutually adjacent.

The base portion 57 overlaps each trench 17 and crosses the side wall of each trench 17 in the first direction X. The base portion 57 has an end portion projecting further to the outer side in the horizontal directions than a region directly below the mesa portion 20. The protrusion portion 58 extends from the base portion 57 to an inner side of the mesa portion 20 along the side wall of the corresponding trench 17 and is connected to a bottom portion of the body region 15. The protrusion portion 58 is formed from the bottom wall of the trench 17 to the body region 15 in the vertical direction Z

The plurality of first contact regions 34A and the plurality of second contact regions 34B penetrate through the body region 15 and the protrusion portion 58 in the vertical direction Z, and are further connected to the base portion 57.

It is noted that, although not shown, the plurality of electric field relaxation structures 21 may be arranged at intervals in the second direction Y instead. In this case, the electric field relaxation structure 21 corresponding to the second contact regions 34B may be formed on the other side in the first direction X with respect to the trench 17 (that is, on a side opposite to the electric field relaxation structure 21 in FIG. 16 with the trench 17 interposed therebetween). The second contact regions 34B are thereby connected to the protrusion portion 58 and the base portion 57 of the electric field relaxation structure 21.

According to this arrangement, the plurality of contact regions 34A and 34B for contact with the electric field relaxation structures 21 are separately located on the one side and the other side of each trench 17 in the width direction (FIG. 16 shows just the first contact regions 34A). The current balance at the time of short circuit can thereby be made uniform, since the channels can be uniformly formed in the length direction of the trenches 17. As a result, the local current concentration on the mesa portion 20 can be prevented and the breakdown resistance can be improved.

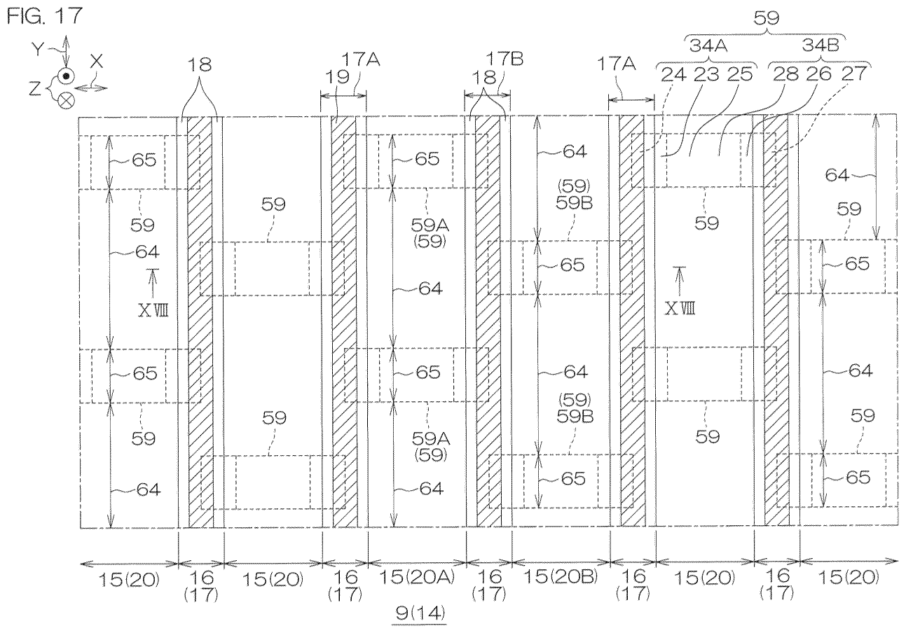

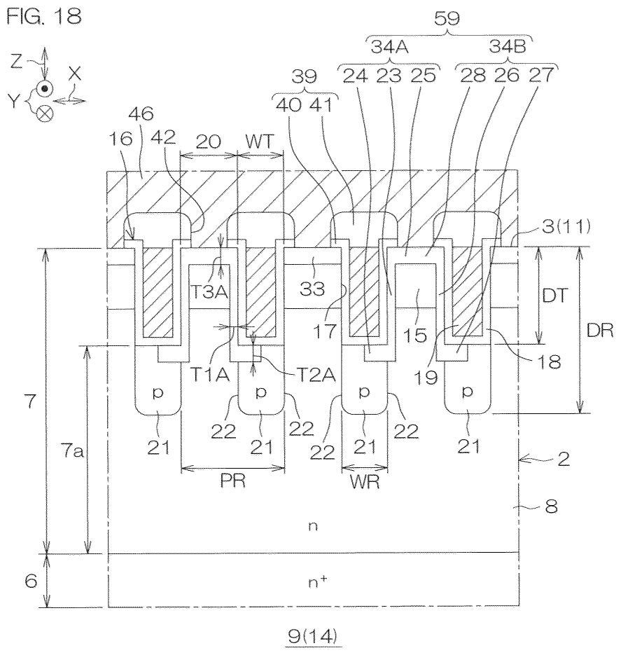

With reference to FIG. 17 and FIG. 18, of the pair of trenches 17A and 17B among the plurality of trenches 17, the first contact region 34A that is formed along the side surface of the one trench 17A and the second contact region 34B that is formed along the side surface of the other trench 17B may be integrated and form one contact region 59 that straddles the one trench 17A and the other trench 17B. It is noted that, in FIG. 17 and FIG. 18, reference signs “17A” and “17B” are shown one by one as an example, but the pair of trenches 17A and 17B may instead be selected from an arbitrary pair of the trenches 17.

The contact regions 59 are arranged in a zigzag pattern in plan view. For example, a pair of the mesa portions 20 of the plurality of mesa portions 20 in the first direction X are defined as a first mesa portion 20A and a second mesa portion 20B. In the first mesa portion 20A, a plurality of contact regions 59A (may be referred to as “first contact regions”) are arranged at intervals in the extension direction of the trench structure 16. In the second mesa portion 20B, a plurality of contact regions 59B (may be referred to as “second contact regions”) are arranged at intervals in the extension direction of the trench structure 16. The plurality of contact regions 59A and the plurality of contact regions 59B are located such as not to overlap each other in the first direction X. The plurality of contact regions 59A and the plurality of contact regions 59B are thereby arranged in a zigzag pattern as a whole.

In each mesa portion 20, a region in which the plurality of contact regions 59 are not formed is a channel section 64. The channel section 64 is a region having a fixed width in the second direction Y. On the other hand, in each mesa portion 20, a region in which the plurality of contact regions 59 are formed is a non-channel section 65. The non-channel section 65 is a region having a fixed width in the second direction Y. In each mesa portion 20, the channel sections 64 and the non-channel sections 65 are alternately arranged in the extension direction of the trench structure 16.

According to this arrangement, the channel sections 64 and the non-channel sections 65 are alternately arranged on both sides of each trench 17. The current balance at the time of short circuit can thereby be made uniform, since the channels can be uniformly formed in the length direction of the trenches 17. As a result, the local current concentration on the mesa portion 20 can be prevented and the breakdown resistance can be improved.

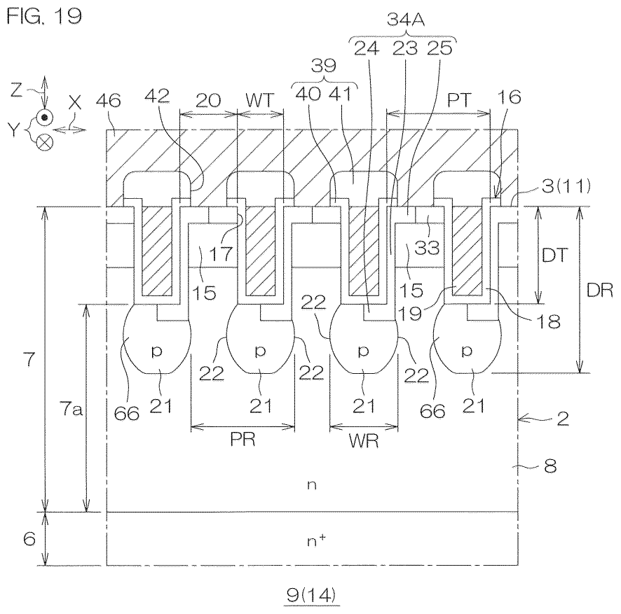

With reference to FIG. 19, the side surface 22 of each electric field relaxation structure 21 does not have to have a planar shape flush with the side surface of the trench 17 in the vertical direction Z, and may have a bulging portion 66 that bulges toward the horizontal direction (at least one of the first direction X and the second direction Y).

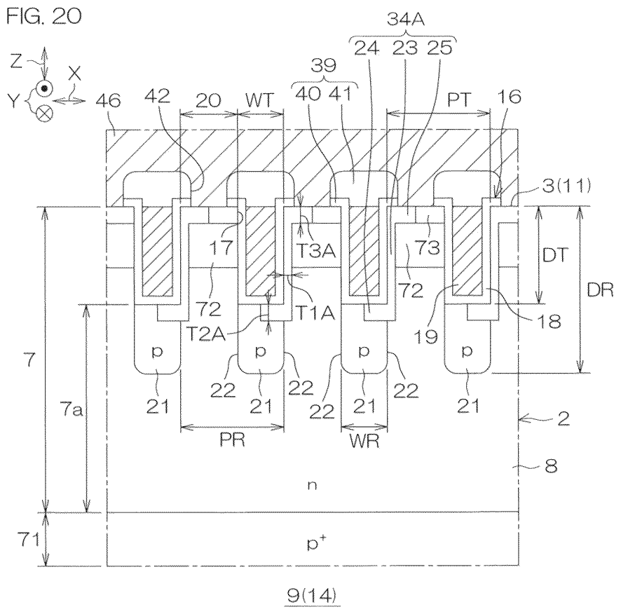

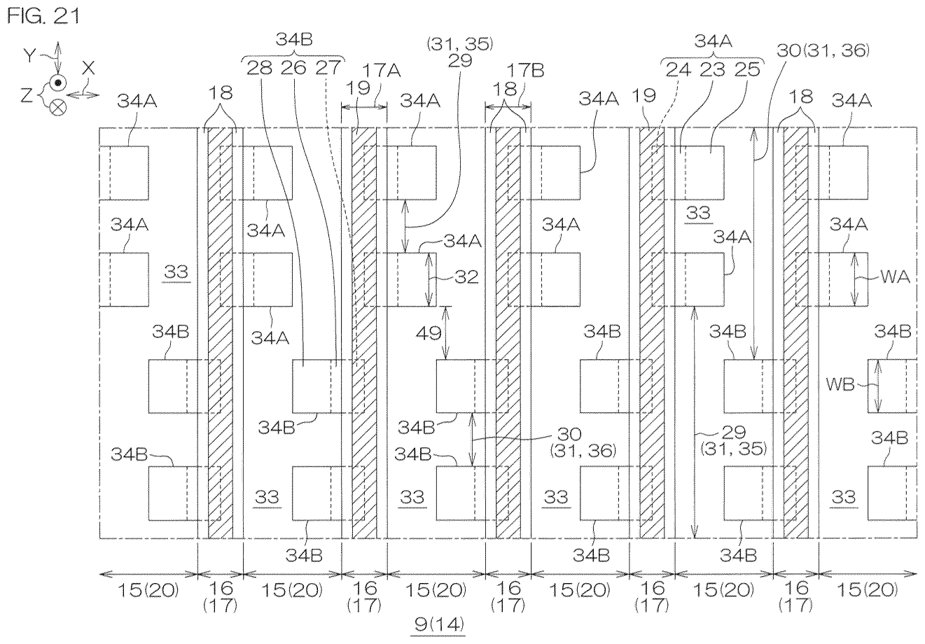

With reference to FIG. 20, an element structure of the semiconductor device 1 may be an IGBT (insulated gate bipolar transistor) structure different from the MISFET structure of FIG. 6 to FIG. 10. In this case, a collector region 71 of the p-type may be formed instead of the base layer 6. Also, a base region 72 of the p-type may be formed by the body region 15, and an emitter region 73 of the n-type may be formed by the source region 33.

According to this arrangement, the plurality of contact regions 34A and 34B for contact with the electric field relaxation structures 21 are separately located on the one side and the other side of each trench 17 in the width direction (FIG. 20 shows just the first contact regions 34A). The current balance at the time of short circuit of the IGBT can thereby be made uniform, since the channels can be uniformly formed in the length direction of the trenches 17. As a result, the local current concentration on the mesa portion 20 can be prevented and the breakdown resistance can be improved.

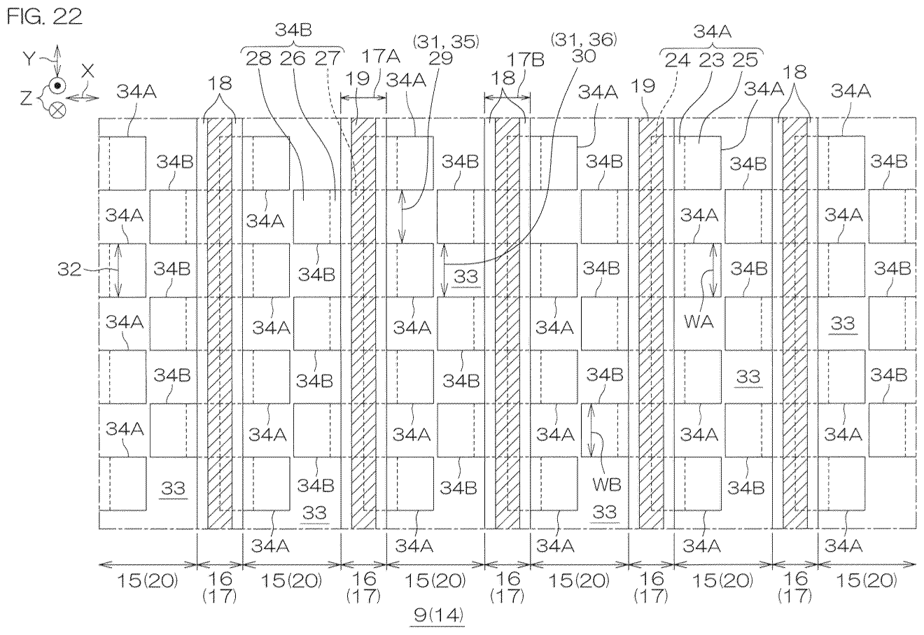

The plurality of first contact regions 34A and the plurality of second contact regions 34B do not have to be arranged one by one alternately on the left and the right at intervals in the second direction Y, and for example, the plurality of first contact regions 34A and the plurality of second contact regions 34B may be arranged alternately on the left and the right at intervals (in FIG. 21, two by two) as shown in FIG. 21, or the plurality of first contact regions 34A and the plurality of second contact regions 34B may be alternately arranged without intervals in the second direction Y as shown in FIG. 22.

Although the preferred embodiment of the present disclosure has been described above, the present disclosure can be implemented in other modes.

For example, with each preferred embodiment described above, the base layer 6 and the semiconductor layer 7 that each include the SiC monocrystal are adopted. However, at least one or all of the base layer 6 and the semiconductor layer 7 may include a monocrystal of a wide bandgap semiconductor other than the SiC monocrystal.

The wide bandgap semiconductor is a semiconductor that has a greater bandgap than the bandgap of silicon. As examples of a monocrystal of a wide bandgap semiconductor, silicon carbide (SiC), gallium nitride (GaN), diamond (C), gallium oxide (Ga₂O₃), etc., can be cited. The base layer 6 and the semiconductor layer 7 may be constituted of monocrystals of the same type or may be constituted of monocrystals of different types. Also, at least one or all of the base layer 6 and the semiconductor layer 7 may be constituted of silicon (Si).

Hereinafter, examples of features extracted from this Description and the attached drawings shall be described. Hereinafter, the alphanumeric characters, etc., in parentheses represent the corresponding components, etc., in the preferred embodiment described above, but are not intended to limit the scope of each clause to the preferred embodiment. The “semiconductor device” in the following clauses may be replaced with an “SiC semiconductor device,” a “wide bandgap semiconductor device,” “a semiconductor switching device,” a “semiconductor rectifier,” a “MISFET device,” an “IGBT device,” a “diode device,” etc., as needed.

### Clause 1-1

A semiconductor device (1) including:
a chip (2) that has a first principal surface (3) and a second principal surface (4) on an opposite side thereto;
a first impurity region (7) of a first conductivity type that is formed in a surface layer portion of the first principal surface (3);
a second impurity region (15) of a second conductivity type that is formed in a surface layer portion of the first impurity region (7);
a third impurity region (33) of the first conductivity type that is formed in a surface layer portion of the second impurity region (15);
a trench (17) that reaches the first impurity region (7) through the third impurity region (33) and the second impurity region (15) from the first principal surface (3);
an electric field relaxation structure (21) of the second conductivity type that is formed at a bottom portion of the trench (17);
a first contact region (34A) that is formed along a side surface on one side of the trench (17) from the first principal surface (3) toward the second principal surface (4) and electrically connected to the second impurity region (15) and the electric field relaxation structure (21); and
a second contact region (34B) that is formed along a side surface on the other side of the trench (17) from the first principal surface (3) toward the second principal surface (4), electrically connected to the second impurity region (15) and the electric field relaxation structure (21), and physically separated from the first contact regions (34A), wherein
a plurality of the first contact regions (34A) and a plurality of the second contact regions (34B) are arranged along a length direction of the trench (17).

According to this arrangement, it is possible to relax concentration of the electric fields on the bottom portion of the trench (17) since the electric field relaxation structure (21) is formed on the bottom portion of the trench (17). Also, since the electric field relaxation structure (21) is connected to the plurality of first contact regions (34A) and the plurality of second contact regions (34B), the electric field relaxation structure (21) can be fixed at a predetermined potential via the plurality of first contact regions (34A) and the plurality of second contact regions (34B).

Also, the plurality of first contact regions (34A) and the plurality of second contact regions (34B) for contact with the electric field relaxation structure (21) are separately located individually on the one side and the other side of the trench (17) in the width direction. The current balance at the time of short circuit can thereby be made uniform, since the channels can be uniformly formed in the length direction of the trench (17). Thus, the local current concentration can be prevented and the breakdown resistance can be improved.

For example, in an embodiment in which the contact regions are selectively formed just on one side of the trench (17) in the width direction, the channel current flows just on the other side of the trench (17) in the width direction. Therefore, the current concentrates on the other side of the trench (17) in the width direction and there are more cases where breakdown occurs at the time of short circuit. On the other hand, in the arrangement described above, since the channels can be uniformly formed in a balanced manner in the length direction of the trench (17), it is possible to prevent the current concentration and improve the breakdown resistance.

### Clause 1-2

The semiconductor device (1) according to Clause 1-1, wherein the first contact regions (34A) and the second contact regions (34B) each integrally have a first portion (23, 26) extending along the side surface of the trench (17) in a depth direction of the trench (17) and having a first thickness (T1A, T1B) from the side surface of the trench (17), and a second portion (24, 27) extending along a bottom surface of the trench (17) from the first portion (23, 26) and having a second thickness (T2A, T2B) from the bottom surface of the trench (17) which is greater than the first thickness (T1A, T1B).

### Clause 1-3

The semiconductor device (1) according to Clause 1-2, wherein the first contact regions (34A) and the second contact regions (34B) each have a third portion (25, 28) formed along the first principal surface (3) from an upper end portion of the first portion (23, 26) toward a side opposite to the trench (17), the third portion (25, 28) being integrally formed with the first portion (23, 26) and the second portion (24, 27).

### Clause 1-4

The semiconductor device (1) according to Clause 1-3, wherein the first portion (23, 26), the second portion (24, 27), and the third portion (25, 28) of the first contact region (34A) and the second contact region (34B) have an equal width (WA, WB) in the length direction of the trench (17).

### Clause 1-5

The semiconductor device (1) according to any one of Clauses 1-1 to 1-4, wherein the plurality of first contact regions (34A) and the plurality of second contact regions (34B) are arranged at intervals along the length direction of the trench (17).

### Clause 1-6

The semiconductor device (1) according to any one of Clauses 1-1 to 1-5, wherein the plurality of first contact regions (34A) and the plurality of second contact regions (34B) are alternately arranged at intervals along the length direction of the trench (17).

### Clause 1-7

The semiconductor device (1) according to Clause 1-6, wherein
a plurality of trenches (17) are arranged at intervals in a first direction (X),
the plurality of first contact regions (34A) are uniformly located, throughout the plurality of trenches (17), on one side of each trench (17) in the first direction (X), and
the plurality of second contact regions (34B) are uniformly located, throughout the plurality of trenches (17), on the other side of each trench (17) in the first direction (X).

### Clause 1-8

The semiconductor device (1) according to Clause 1-7, wherein, of a pair of the trenches (17A, 17B) among the plurality of trenches (17), at positions adjacent in the first direction (X) with respect to regions (29) between the plurality of first contact regions (34A) of the one trench (17A), the second contact regions (34B) of the other trench (17B) are located.

### Clause 1-9

The semiconductor device (1) according to Clause 1-8, wherein, in a mesa portion (20) of the chip (2) sandwiched between the pair of trenches (17), the third impurity region (33) passes between the plurality of first contact regions (34A) and the plurality of second contact regions (34B) and is formed in a zigzag shape along a second direction (Y) intersecting the first direction (X).

### Clause 1-10

The semiconductor device (1) according to any one of Clauses 1-1 to 1-9, wherein the electric field relaxation structure (21) has side surfaces (22) flush with both side surfaces of the trench (17) in a depth direction of the trench (17).

### Clause 1-11

The semiconductor device (1) according to any one of Clauses 1-1 to 1-10, wherein the electric field relaxation structure (21) has a bulging portion (66) that bulges in a lateral direction from at least one side surface of both of the side surfaces of the trench (17).

### Clause 1-12

The semiconductor device (1) according to any one of Clauses 1-1 to 1-4, 1-10, and 1-11, wherein
a plurality of the trenches (17) are arranged at intervals, and
the first contact region (34A) that is formed along a side surface of one trench (17A) and the second contact region (34B) that is formed along a side surface of the other trench (17B) of a pair of the trenches (17A, 17B) of the plurality of trenches (17) are integrated and form one contact region (59) that straddles the one trench (17A) and the other trench (17B).

### Clause 1-13

The semiconductor device (1) according to any one of Clauses 1-1 to 1-12, including:
a drain region (6) of the first conductivity type that is formed on the second principal surface (4) side with respect to the first impurity region (7);
a body region (15) that is formed by the second impurity region (15);
a source region (33) that is formed by the third impurity region (33); and
a trench gate structure (16) that is formed by the trench (17), an insulating film (18) covering a wall surface of the trench (17), and an embedded electrode (19) embedded in the trench (17).

### Clause 1-14

The semiconductor device (1) according to any one of Clauses 1-1 to 1-12, including:
a collector region (71) of the second conductivity type that is formed on the second principal surface (4) side with respect to the first impurity region (7);
a base region (72) that is formed by the second impurity region (15);
an emitter region (73) that is formed by the third impurity region (33); and
a trench gate structure (16) that is formed by the trench (17), an insulating film (18) covering the wall surface of the trench (17), and an embedded electrode (19) embedded in the trench (17).

### Clause 1-15

The semiconductor device (1) according to any one of Clauses 1-1 to 1-14, wherein the chip (2) includes an SiC chip (2).

1. A semiconductor device comprising:
a chip that has a first principal surface and a second principal surface on an opposite side thereto;
a first impurity region of a first conductivity type that is formed in a surface layer portion of the first principal surface;
a second impurity region of a second conductivity type that is formed in a surface layer portion of the first impurity region;
a third impurity region of the first conductivity type that is formed in a surface layer portion of the second impurity region;
a trench that reaches the first impurity region through the third impurity region and the second impurity region from the first principal surface;
an electric field relaxation structure of the second conductivity type that is formed at a bottom portion of the trench;
a first contact region that is formed along a side surface on one side of the trench from the first principal surface toward the second principal surface and electrically connected to the second impurity region and the electric field relaxation structure; and
a second contact region that is formed along a side surface on the other side of the trench from the first principal surface toward the second principal surface, electrically connected to the second impurity region and the electric field relaxation structure, and physically separated from the first contact regions, wherein
a plurality of the first contact regions and a plurality of the second contact regions are arranged along a length direction of the trench.

2. The semiconductor device according to claim 1, wherein the first contact regions and the second contact regions each integrally have a first portion extending along the side surface of the trench in a depth direction of the trench and having a first thickness from the side surface of the trench, and a second portion extending along a bottom surface of the trench from the first portion and having a second thickness from the bottom surface of the trench which is greater than the first thickness.

3. The semiconductor device according to claim 2, wherein the first contact regions and the second contact regions each have a third portion formed along the first principal surface from an upper end portion of the first portion toward a side opposite to the trench, the third portion being integrally formed with the first portion and the second portion.

4. The semiconductor device according to claim 3, wherein the first portion, the second portion, and the third portion of the first contact region and the second contact region have an equal width in the length direction of the trench.

5. The semiconductor device according to claim 1, wherein the plurality of first contact regions and the plurality of second contact regions are arranged at intervals along the length direction of the trench.

6. The semiconductor device according to claim 1, wherein the plurality of first contact regions and the plurality of second contact regions are alternately arranged at intervals along the length direction of the trench.

7. The semiconductor device according to claim 6, wherein
a plurality of trenches are arranged at intervals in a first direction,
the plurality of first contact regions are uniformly located, throughout the plurality of trenches, on one side of each trench in the first direction, and
the plurality of second contact regions are uniformly located, throughout the plurality of trenches, on the other side of each trench in the first direction.

8. The semiconductor device according to claim 7, wherein, of a pair of the trenches among the plurality of trenches, at positions adjacent in the first direction with respect to regions between the plurality of first contact regions of the one trench, the second contact regions of the other trench are located.

9. The semiconductor device according to claim 8, wherein, in a mesa portion of the chip sandwiched between the pair of trenches, the third impurity region passes between the plurality of first contact regions and the plurality of second contact regions and is formed in a zigzag shape along a second direction intersecting the first direction.

10. The semiconductor device according to claim 1, wherein the electric field relaxation structure has side surfaces flush with both side surfaces of the trench in a depth direction of the trench.

11. The semiconductor device according to claim 1, wherein the electric field relaxation structure has a bulging portion that bulges in a lateral direction from at least one side surface of both of the side surfaces of the trench.

12. The semiconductor device according to claim 1, wherein
a plurality of the trenches are arranged at intervals, and
the first contact region that is formed along a side surface of one trench and the second contact region that is formed along a side surface of the other trench of a pair of the trenches of the plurality of trenches are integrated and form one contact region that straddles the one trench and the other trench.

13. The semiconductor device according to claim 1, comprising:
a drain region of the first conductivity type that is formed on the second principal surface side with respect to the first impurity region;
a body region that is formed by the second impurity region;
a source region that is formed by the third impurity region; and
a trench gate structure that is formed by the trench, an insulating film covering the wall surface of the trench, and an embedded electrode embedded in the trench.

14. The semiconductor device according to claim 1, comprising:
a collector region of the second conductivity type that is formed on the second principal surface side with respect to the first impurity region;
a base region that is formed by the second impurity region; and
an emitter region that is formed by the third impurity region; and
a trench gate structure that is formed by the trench, an insulating film covering the wall surface of the trench, and an embedded electrode embedded in the trench.

15. The semiconductor device according to claim 1, wherein the chip includes an SiC chip.
